(19) United States
(12) Patent Application Publication
(10) Pub. No.: US 2025/0301730 A1
(43) Pub. Date: Sep. 25, 2025

(54) SEMICONDUCTOR DEVICE

(71) Applicant: Samsung Electronics Co., Ltd., Suwon-si (KR)

(72) Inventors: Seung Hyeok CHOI, Suwon-si (KR); Ki-Il KIM, Suwon-si (KR); Jung Hyun KIM, Suwon-si (KR)

(21) Appl. No.: 18/894,687

(22) Filed: Sep. 24, 2024

(30) Foreign Application Priority Data
Mar. 19, 2024 (KR) 10-2024-0037549

(51) Int. Cl. H01L 29/06; H01L 29/08; H01L 29/417; H01L 29/423; H01L 29/66; H01L 29/775; H01L 29/78; H01L 29/786

(52) U.S. Cl. CPC H10D 62/121; H10D 30/014; H10D 30/43; H10D 30/6735; H10D 30/6757; H10D 30/797; H10D 62/151; H10D 64/017; H10D 64/251

(57) ABSTRACT

A semiconductor device is provided that includes a lower interlayer insulating layer, an insulating pattern on the lower interlayer insulating layer and extending in a first horizontal direction, a plurality of semiconductor nanosheets stacked on an upper surface of the insulating pattern, a gate electrode that extends in a second horizontal direction and surrounding the plurality of semiconductor nanosheets, a first source/drain region disposed on the insulating pattern at a first side of the gate electrode, a second source/drain region disposed on the insulating pattern at a second side of the gate electrode opposite to the first side of the gate electrode, a lower source/drain contact that penetrates the lower interlayer insulating layer and the insulating pattern, the lower source/drain contact electrically connected to the second source/drain region, and a first insulating liner layer in contact with both sidewalls of the first portion of the lower source/drain contact.

### CROSS-REFERENCE TO RELATED APPLICATION

This application claims priority from Korean Patent Application No. 10-2024-0037549 filed on Mar. 19, 2024, in the Korean Intellectual Property Office, and all the benefits accruing therefrom under 35 U.S.C. 119, the contents of which in its entirety are herein incorporated by reference.

### BACKGROUND

### Technical Field

The present disclosure relates to a semiconductor device. Specifically, the present disclosure relates to a semiconductor device including an MBCFET™ (Multi-Bridge Channel Field Effect Transistor).

### Description of Related Art

A scaling scheme for increasing an integration density of an integrated circuit device employs a multi-gate transistor in which a silicon body in a shape of a fin or a nanowire is formed on a substrate and a gate is formed on a surface of the silicon body.

Because such a multi-gate transistor uses a three-dimensional channel, it is easy to scale the same. Further, current control capability of the multi-gate transistor may be improved without increasing a gate length of the multi-gate transistor. In addition, the multi-gate transistor may effectively suppress SCE (short channel effect) in which potential of a channel region is affected by drain voltage.

### SUMMARY

The present disclosure describes a semiconductor device in which reliability of electrical connection between a source/drain region and a lower source/drain contact disposed in a backside region is improved.

According to some embodiments of the present disclosure, there is provided a semiconductor device, comprising a lower interlayer insulating layer, an insulating pattern disposed on an upper surface of the lower interlayer insulating layer, the insulating pattern extending in a first horizontal direction, a plurality of semiconductor nanosheets stacked on an upper surface of the insulating pattern with each semiconductor nanosheet of the plurality spaced apart from each other in a vertical direction, a gate electrode that extends in a second horizontal direction different from the first horizontal direction on the insulating pattern, the gate electrode surrounding the plurality of semiconductor nanosheets, a first source/drain region disposed on the insulating pattern at a first side of the gate electrode, a second source/drain region disposed on the insulating pattern at a second side of the gate electrode opposite to the first side of the gate electrode in the first horizontal direction, a lower source/drain contact that penetrates through the lower interlayer insulating layer and the insulating pattern in the vertical direction, the lower source/drain contact electrically connected to the second source/drain region, the lower source/drain contact including a first portion disposed under the second source/drain region, and a second portion disposed under the first portion, and a first insulating liner layer in contact with both sidewalls of the first portion of the lower source/drain contact in the first horizontal direction, an upper surface of the first insulating liner layer being in contact with the second source/drain region.

According to some embodiments of the present disclosure, there is provided a semiconductor device, comprising a lower interlayer insulating layer, an insulating pattern disposed on an upper surface of the lower interlayer insulating layer, the insulating pattern extending in a first horizontal direction, a field insulating layer disposed on the upper surface of the lower interlayer insulating layer, the field insulating layer covering a sidewall of the insulating pattern, a gate electrode on the insulating pattern and the field insulating layer, the gate electrode extending in a second horizontal direction different from the first horizontal direction, a first source/drain region disposed on the insulating pattern at a first side of the gate electrode, a second source/drain region disposed on the insulating pattern at a second side of the gate electrode opposite to the first side of the gate electrode in the first horizontal direction, a lower source/drain contact that penetrates through the lower interlayer insulating layer and the insulating pattern in a vertical direction, the lower source/drain contact electrically connected to the second source/drain region, a sacrificial pattern being in contact with a lower surface of the first source/drain region, the sacrificial pattern comprising silicon germanium (SiGe), a first insulating liner layer being in contact with both sidewalls of the sacrificial pattern in the first horizontal direction, an upper surface of the first insulating liner layer being in contact with the first source/drain region, and a second insulating liner layer in contact with at least a portion of both sidewalls of the lower source/drain contact in the first horizontal direction, an upper surface of the second insulating liner layer being in contact with the second source/drain region, a vertical level of the upper surface of the second insulating liner layer is lower than a vertical level of an upper surface of the field insulating layer.

According to some embodiments of the present disclosure, there is provided a semiconductor device, comprising a lower interlayer insulating layer, an insulating pattern extending in a first horizontal direction on an upper surface of the lower interlayer insulating layer, a plurality of semiconductor nanosheets stacked on an upper surface of the insulating pattern with each semiconductor nanosheet of the plurality spaced apart from each other in a vertical direction, a field insulating layer disposed on the upper surface of the lower interlayer insulating layer, the field insulating layer that covers a sidewall of the insulating pattern, a gate electrode extending in a second horizontal direction different from the first horizontal direction on the insulating pattern, the gate electrode surrounding each semiconductor nanosheet the plurality of semiconductor nanosheets, a first source/drain region disposed on the insulating pattern at on a first side of the gate electrode, a second source/drain region disposed on the insulating pattern at a second side of the gate electrode opposite to the first side of the gate electrode in the first horizontal direction, an upper interlayer insulating layer that covers the first and second source/drain regions on the field insulating layer, an upper source/drain contact that penetrates through the upper interlayer insulating layer in the vertical direction, the upper source/drain contact electrically connected to the first source/drain region, a lower source/drain contact that penetrates through the lower interlayer insulating layer and the insulating pattern in the vertical direction, the lower source/drain contact electrically connected to the second source/drain region, the lower source/drain contact including a first portion disposed under the second source/drain region, and a second portion disposed under the first portion, a sacrificial pattern in contact with a lower surface of the first source/drain region, the sacrificial pattern comprising silicon germanium (SiGe), a first insulating liner layer in contact with both sidewalls in the first horizontal direction of the sacrificial pattern, an upper surface of the first insulating liner layer in contact with the first source/drain region, a vertical level of a lower surface of the first insulating liner layer being higher than a vertical level of a lower surface of the sacrificial pattern, and a second insulating liner layer in contact with both sidewalls in the first horizontal direction of the first portion of the lower source/drain contact, an upper surface of the second insulating liner layer in contact with the second source/drain region, a vertical level of the upper surface of the second insulating liner layer being lower than a vertical level of an upper surface of the field insulating layer, a lower surface of the second insulating liner layer in contact with an upper surface of the second portion of the lower source/drain contact.

The purpose and benefits of embodiments according to the present disclosure are not limited to the above-mentioned embodiments. Other purposes and advantages according to the present disclosure that are not mentioned may be understood based on following descriptions, and may be more clearly understood based on the description of illustrative embodiments according to the present disclosure. Further, it will be easily understood that the purposes and advantages according to the present disclosure may be realized using means shown in the claims and combinations thereof.

### BRIEF DESCRIPTION OF DRAWINGS

The above and other aspects and features of the present disclosure will become more apparent by describing in detail exemplary embodiments thereof with reference to the attached drawings, in which:

FIG. 1 is a layout diagram illustrating a semiconductor device according to some embodiments of the present disclosure;

FIG. 2 is a cross-sectional view cut along a line A-A′ in FIG. 1;

FIG. 3 is a cross-sectional view cut along a line B-B′ in FIG. 1;

FIG. 4 is a cross-sectional view cut along a line C-C′ in FIG. 1;

FIGS. 5, 6, 7, 8, 9, 10, 11, 12, 13, 14, 15, 16, 17, 18, 19, 20, 21, 22, 23, 24, 25, 26, 27, 28, 29, 30, 31, 32, 33, 34, 35, 36, and 37 are diagrams illustrating intermediate structures corresponding to intermediate steps of a method for fabricating a semiconductor device according to some embodiments of the present disclosure;

FIG. 38 and FIG. 39 are cross-sectional views illustrating a semiconductor device according to other embodiments of the present disclosure;

FIG. 40 and FIG. 41 are cross-sectional views illustrating a semiconductor device according to other embodiments of the present disclosure; and

FIG. 42 and FIG. 43 are cross-sectional views illustrating a semiconductor device according to other embodiments of the present disclosure.

### DETAILED DESCRIPTIONS

The present disclosure now will be described more fully hereinafter with reference to the accompanying drawings, in which various embodiments are shown. The present disclosure may, however, be embodied in many different forms and should not be construed as limited to the example embodiments set forth herein. It should also be emphasized that the disclosure provides details of alternative examples, but such listing of alternatives is not exhaustive. Furthermore, any consistency of detail between various examples should not be interpreted as requiring such detail. The language of the claims should be referenced in determining the requirements of the present disclosure.

As used herein, the term “dummy” is used to refer to a component that has the same or similar structure and shape as a related non-dummy component, but does not perform a substantial function provided by the related non-dummy component. In some instances, a “dummy” component may be electrically floated, or may be connected to various voltage sources but otherwise not provide the same functionality of the non-dummy component it represents. For example, a dummy word line may not connect to memory cells, or may have dummy memory cells connected to it (where no data is read from the dummy memory cells). In some instances, a “dummy” element may also be a “sacrificial” element.

As used herein, the term “sacrificial” is used to refer to a component that has the same or similar structure and shape as a related non-sacrificial component, but may be formed of a different material and does not perform a substantial function provided by the related non-sacrificial component. Furthermore, some sacrificial components may be removed during manufacturing and replaced by a non-sacrificial component, but in such instances portions of the sacrificial component may remain in the finished product as are still referred to as a sacrificial component.

Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

As used herein, components described as being “electrically connected” are configured such that an electrical signal can be transferred from one component to the other (although such electrical signal may be attenuated in strength as it is transferred and may be selectively transferred). Moreover, components that are “directly electrically connected” form a common electrical node through electrical connections by one or more conductors, such as, for example, wires, pads, internal electrical lines, through vias, etc. As such, directly electrically connected components do not include components electrically connected through active elements, such as transistors or diodes.

Terms such as “same,” “equal,” “planar,” “coplanar,” “parallel,” and “perpendicular,” as used herein encompass identicality or near identicality including variations that may occur resulting from conventional manufacturing processes. The term “substantially” may be used herein to emphasize this meaning, unless the context or other statements indicate otherwise.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first”) in a particular claim may be described elsewhere with a different ordinal number (e.g., “second”) in the specification or another claim.

Hereinafter, in the drawings related to a semiconductor device according to some embodiments, an example in which the semiconductor device includes a transistor MBCFET™ (Multi-Bridge Channel Field Effect Transistor) including a nanosheet is described. However, the present disclosure is not limited thereto. In some embodiments, the semiconductor device may include a fin-shaped transistor (FinFET) including a channel region of a fin shaped pattern, a tunneling FET, or a three-dimensional 3D transistor. Additionally, a semiconductor device according to some embodiments may include a bipolar junction transistor or a lateral double diffused MOS transistor (LDMOS). The semiconductor device may be a semiconductor chip in which an integrated circuit is formed, such as by logic circuits formed by interconnecting the transistors described herein.

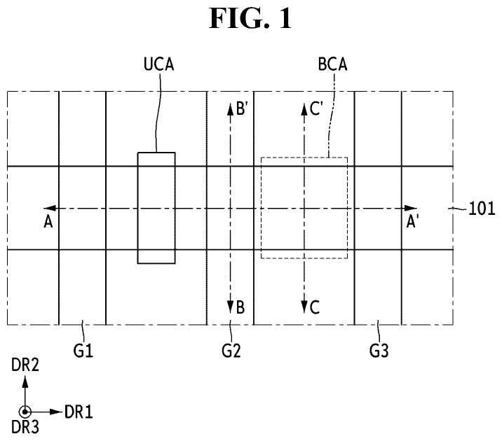

Hereinafter, a semiconductor device according to some embodiments of the present disclosure is described with reference to FIGS. 1 to 4.

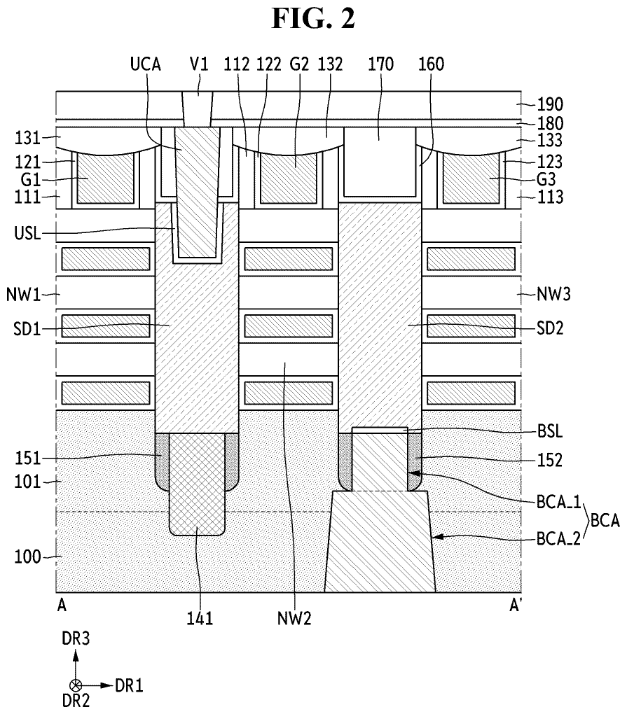

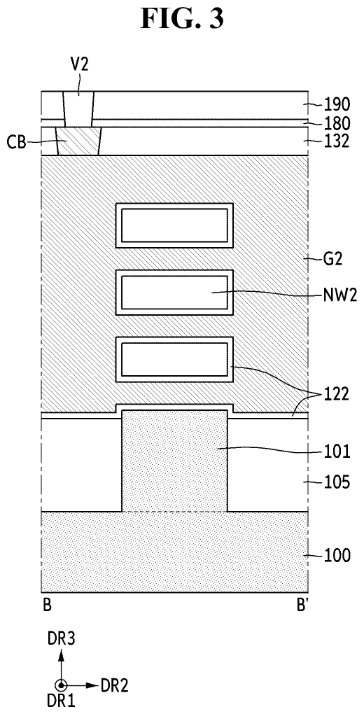

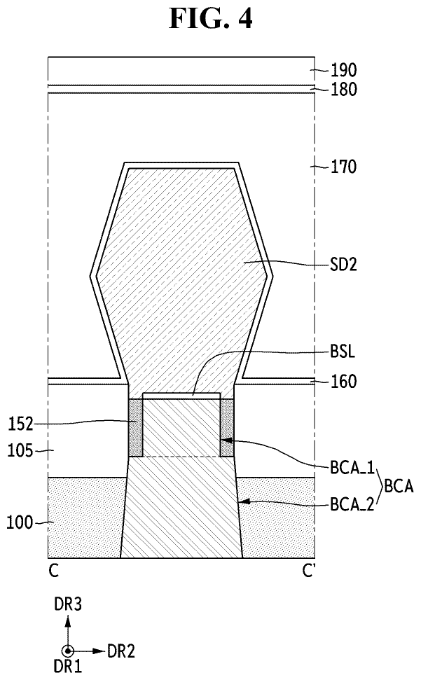

FIG. 1 is a layout diagram illustrating a semiconductor device according to some embodiments of the present disclosure. FIG. 2 is a cross-sectional view cut along a line A-A′ in FIG. 1. FIG. 3 is a cross-sectional view cut along a line B-B′ in FIG. 1. FIG. 4 is a cross-sectional view cut along a line C-C′ in FIG. 1.

Referring to FIGS. 1 to 4, the semiconductor device according to some embodiments of the present disclosure includes a lower interlayer insulating layer 100, an insulating pattern 101, a field insulating layer 105, first to third pluralities of nanosheets NW1, NW2, and NW3, first to third gate electrodes G1, G2, and G3, first to third gate spacers 111, 112, and 113, first to third gate insulating layers 121, 122, and 123, first to third capping patterns 131, 132, and 133, first and second source/drain regions SD1a and SD2, a first sacrificial pattern 141, first and second insulating liner layers 151 and 152, a first etching stop layer 160, a first upper interlayer insulating layer 170, a gate contact CB, an upper source/drain contact UCA, a lower source/drain contact BCA, an upper silicide layer USL, a lower silicide layer BSL, a second etching stop layer 180, a second upper interlayer insulating layer 190, and first and second vias V1 and V2.

The lower interlayer insulating layer 100 may include at least one of silicon oxide, silicon nitride, silicon oxynitride, or a low dielectric constant material. The low dielectric constant material may include, for example, fluorinated tetraethylorthosilicate (FTEOS), hydrogen silsesquioxane (HSQ), bis-benzocyclobutene (BCB), tetramethylorthosilicate (TMOS), octamethyleyclotetrasiloxane (OMCTS), hexamethyldisiloxane (HMDS), trimethylsilyl borate (TMSB), diacetoxyditertiarybutosiloxane (DADBS), trimethylsilil phosphate (TMSP), polytetrafluoroethylene (PTFE), TOSZ (Tonen SilaZen), FSG (fluoride silicate glass), polyimide nanofoams such as polypropylene oxide, CDO (carbon doped silicon oxide), OSG (organo silicate glass), SiLK, amorphous fluorinated carbon, silica aerogels, silica xerogels, mesoporous silica, or combinations thereof. However, the spirit of the present disclosure is not limited thereto.

Hereinafter, each of a first horizontal direction DR1 and a second horizontal direction DR2 may be defined as a direction parallel to an upper surface of the lower interlayer insulating layer 100. The second horizontal direction DR2 may be defined as a direction different from the first horizontal direction DR1. A vertical direction DR3 may be defined as a direction perpendicular to each of the first horizontal direction DR1 and the second horizontal direction DR2. That is, the vertical direction DR3 may be defined as a direction perpendicular to the upper surface of the lower interlayer insulating layer 100.

The insulating pattern 101 may extend in the first horizontal direction DR1 and may be disposed on the upper surface of the lower interlayer insulating layer 100. The insulating pattern 101 may protrude in the vertical direction DR3 from the upper surface of the lower interlayer insulating layer 100. The insulating pattern 101 may include an insulating material. For example, the insulating pattern 101 may include the same material as that of the lower interlayer insulating layer 100.

The field insulating layer 105 may be disposed on the upper surface of the lower interlayer insulating layer 100. The field insulating layer 105 may surround and/or cover a sidewall of the insulating pattern 101. The upper surface of the insulating pattern 101 may protrude in the vertical direction DR3 beyond the upper surface of the field insulating layer 105. However, the present disclosure is not limited thereto. In some embodiments, the upper surface of the insulating pattern 101 may be coplanar with the upper surface of the field insulating layer 105. The field insulating layer 105 may include, for example, an oxide film, a nitride film, an oxynitride film, or a combination thereof.

The first plurality of nanosheets NW1 may be disposed on the insulating pattern 101. The first plurality of nanosheets NW1 may be disposed in a region where the insulating pattern 101 and the first gate electrode G1 intersect each other. The second plurality of nanosheets NW2 may be disposed on the insulating pattern 101. The second plurality of nanosheets NW2 may be disposed in a region where the insulating pattern 101 and the second gate electrode G2 intersect each other. The second plurality of nanosheets NW2 may be spaced apart from the first plurality of nanosheets NW1 in the first horizontal direction DR1. The third plurality of nanosheets NW3 may be disposed on the insulating pattern 101. The third plurality of nanosheets NW3 may be disposed in a region where the insulating pattern 101 and the third gate electrode G3 intersect each other. The third plurality of nanosheets NW3 may be spaced apart from the second plurality of nanosheets NW2 in the first horizontal direction DR1.

Each of the first to third pluralities of nanosheets NW1, NW2, and NW3 may include a plurality of nanosheets stacked with the individual nanosheets of each plurality spaced apart from each other in the vertical direction DR3. In FIG. 2 and FIG. 3, each of the first to third pluralities of nanosheets NW1, NW2, and NW3 is shown as including three nanosheets stacked and spaced apart from each other in the vertical direction DR3. However, this is for convenience of the illustration, and the present disclosure is not limited thereto. In some embodiments, each of the first to third pluralities of nanosheets NW1, NW2, and NW3 may include four or more nanosheets that are stacked and spaced apart from each other in the vertical direction DR3. Each nanosheet may be a two-dimensional nanostructure with a thickness in a scale ranging from 1 to 100 nm. Each nanosheet of the first to third pluralities of nanosheets NW1, NW2, and NW3 may be a semiconductor nanosheet. For example, each nanosheet of the first to third pluralities of nanosheets NW1, NW2, and NW3 may include silicon (Si). However, the present disclosure is not limited thereto. In some embodiments, each nanosheet of the first to third pluralities of nanosheets NW1, NW2, and NW3 may include silicon germanium (SiGe).

The first gate electrode G1 may extend in the second horizontal direction DR2 and be disposed on the insulating pattern 101 and the field insulating layer 105. The first gate electrode G1 may surround the first plurality of nanosheets NW1 (e.g., each nanosheet of the plurality of nanosheets NW1 may be surrounded by the first gate electrode and the first gate electrode may extend in each space between adjacent nanosheets). The second gate electrode G2 may extend in the second horizontal direction DR2 and be disposed on the insulating pattern 101 and the field insulating layer 105. The second gate electrode G2 may surround the second plurality of nanosheets NW2. The second gate electrode G2 may be spaced apart from the first gate electrode G1 in the first horizontal direction DR1. The third gate electrode G3 may extend in the second horizontal direction DR2 and be disposed on the insulating pattern 101 and the field insulating layer 105. The third gate electrode G3 may surround the third plurality of nanosheets NW3. The third gate electrode G3 may be spaced apart from the second gate electrode G2 in the first horizontal direction DR1.

Each of the first to third gate electrodes G1, G2, and G3 may include, for example, at least one of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC—N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V) or combinations thereof. Each of the first to third gate electrodes G1, G2, and G3 may include a conductive metal oxide, a conductive metal oxynitride, or the like, or may include an oxidized product of the above-mentioned material.

The first gate spacer 111 may be disposed on an upper surface of the uppermost nanosheet of the first plurality of nanosheets NW1 and the field insulating layer 105 and may extend along both opposing sidewalls of the first gate electrode G1 and in the second horizontal direction DR2. The second gate spacer 112 may be disposed on an upper surface of the uppermost nanosheet of the second plurality of nanosheets NW2 and the field insulating layer 105 and may extend along both opposing sidewalls of the second gate electrode G2 and in the second horizontal direction DR2. The third gate spacer 113 may be disposed on an upper surface of the uppermost nanosheet of the third plurality of nanosheets NW3 and the field insulating layer 105 and may extend along both opposing sidewalls of the third gate electrode G3 and in the second horizontal direction DR2.

Each of the first to third gate spacers 111, 112, and 113 may include, for example, at least one of silicon nitride (SiN), silicon oxynitride (SiON), silicon oxide (SiO₂), silicon oxycarbonitride (SiOCN), silicon boron nitride (SiBN), silicon oxyboron nitride (SiOBN), silicon oxycarbide (SiOC), or combinations thereof. However, the present disclosure is not limited thereto.

The first source/drain region SD1 may be disposed between the first gate electrode G1 and the second gate electrode G2 and on the insulating pattern 101. The first source/drain region SD1 may be in contact with a sidewall facing in the first horizontal direction DR1 of the first plurality of nanosheets NW1 and a sidewall facing in the first horizontal direction DR1 of the first plurality of nanosheets NW2. The second source/drain region SD2 may be disposed between the second gate electrode G2 and the third gate electrode G3 and on the insulating pattern 101. The second source/drain region SD2 may be in contact with a sidewall facing in the first horizontal direction DR1 of the second plurality of nanosheets NW2 and a sidewall facing in the first horizontal direction DR1 of the third plurality of nanosheets NW3.

A lower surface of each of the first and second source/drain regions SD1 and SD2 may be positioned at a lower vertical level than that of the upper surface of the insulating pattern 101. A portion of a sidewall facing in the first horizontal direction DR1 of each of the first and second source/drain regions SD1 and SD2 may contact the insulating pattern 101. A lower surface of each of the first and second source/drain regions SD1 and SD2 may be positioned at a lower vertical level than that of the upper surface of the field insulating layer 105. A portion of a sidewall facing in the second horizontal direction DR2 of each of the first and second source/drain regions SD1 and SD2 may contact the field insulating layer 105. An upper surface of each of the first and second source/drain regions SD1 and SD2 may be positioned at a higher vertical level than that of the upper surface of the uppermost nanosheets of each of the first to third plurality of nanosheets NW1, NW2, and NW3.

The first gate insulating layer 121 may be disposed between the first gate electrode G1 and the insulating pattern 101. The first gate insulating layer 121 may be disposed between the first gate electrode G1 and the field insulating layer 105. The first gate insulating layer 121 may be disposed between the first gate electrode G1 and the first gate spacer 111. The first gate insulating layer 121 may be disposed between the first gate electrode G1 and the first plurality of nanosheets NW1. The first gate insulating layer 121 may be disposed between the first gate electrode G1 and the first source/drain region SD1.

The second gate insulating layer 122 may be disposed between the second gate electrode G2 and the insulating pattern 101. The second gate insulating layer 122 may be disposed between the second gate electrode G2 and the field insulating layer 105. The second gate insulating layer 122 may be disposed between the second gate electrode G2 and the second gate spacer 112. The second gate insulating layer 122 may be disposed between the second gate electrode G2 and the second plurality of nanosheets NW2. The second gate insulating layer 122 may be disposed between the second gate electrode G2 and each of the first and second source/drain regions SD1 and SD2.

The third gate insulating layer 123 may be disposed between the third gate electrode G3 and the insulating pattern 101. The third gate insulating layer 123 may be disposed between the third gate electrode G3 and the field insulating layer 105. The third gate insulating layer 123 may be disposed between the third gate electrode G3 and the third gate spacer 113. The third gate insulating layer 123 may be disposed between the third gate electrode G3 and the third plurality of nanosheets NW3. The third gate insulating layer 123 may be disposed between the third gate electrode G3 and the second source/drain region SD2.

Each of the first to third gate insulating layers 121, 122, and 123 may be in contact with the insulating pattern 101. Each of the first and second gate insulating layers 121 and 122 may contact the first source/drain region SD1. Additionally, each of the second and third gate insulating layers 122 and 123 may be in contact with the second source/drain region SD2. However, the present disclosure is not limited thereto. In some embodiments, an inner spacer may be disposed between each of the first and second gate insulating layers 121 and 122 and the first source/drain region SD1. Additionally, an inner spacer may be disposed between each of the second and third gate insulating layers 122 and 123 and the second source/drain region SD2. The inner spacer may include, for example, at least one of silicon nitride (SiN), silicon oxynitride (SiON), silicon oxide (SiO₂), silicon oxycarbonitride (SiOCN), silicon boron nitride (SiBN), silicon oxyboron nitride (SiOBN), silicon oxycarbide (SiOC), or combinations thereof. The present disclosure is not limited thereto.

Each of the first to third gate insulating layers 121, 122, and 123 may include at least one of silicon oxide, silicon oxynitride, silicon nitride, or a high dielectric constant material having a higher dielectric constant than that of silicon oxide. The high dielectric constant material may include at least one of, for example, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, or lead zinc niobate.

The semiconductor device according to some embodiments may include an NC (negative capacitance) FET using a negative capacitor. Each of the first to third gate insulating layers 121, 122, and 123 may include a ferroelectric material film having ferroelectric properties and a paraelectric material film having paraelectric properties.

The ferroelectric material film may have negative capacitance, and the paraelectric material film may have positive capacitance. For example, when two or more capacitors are connected in series to each other, and the capacitance of each of the capacitors has a positive value, a total capacitance is smaller than the capacitance of each individual capacitor. On the contrary, when at least one of the capacitances of the two or more capacitors connected in series to each other has a negative value, a total capacitance may have a positive value and be greater than an absolute value of each individual capacitance.

When the ferroelectric material film with negative capacitance and the paraelectric material film with positive capacitance are connected in series to each other, a total capacitance value of the ferroelectric material film and the paraelectric material film connected in series to each other may be increased. Using the increase in the total capacitance value, a transistor including the ferroelectric material film may have a subthreshold swing (SS) lower than 60 mV/decade at room temperature.

The ferroelectric material film may have ferroelectric properties. The ferroelectric material film may include, for example, at least one of hafnium oxide, hafnium zirconium oxide, barium strontium titanium oxide, barium titanium oxide, or lead zirconium titanium oxide. In this connection, in one example, hafnium zirconium oxide may refer to a material obtained by doping hafnium oxide with zirconium (Zr). In another example, hafnium zirconium oxide may refer to a compound of hafnium (Hf), zirconium (Zr), and oxygen (O).

The ferroelectric material film may further contain doped dopants. For example, the dopant may include at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), or tin (Sn). A type of the dopant contained in the ferroelectric material film may vary depending on a type of the ferroelectric material included in the ferroelectric material film.

When the ferroelectric material film includes hafnium oxide, the dopant contained in the ferroelectric material film may include, for example, at least one of gadolinium (Gd), silicon (Si), zirconium (Zr), aluminum (Al), or yttrium (Y).

When the dopant is aluminum (Al), the ferroelectric material film may contain 3 to 8 at % (atomic %) of aluminum. In this connection, a content of the dopant may be a content of aluminum based on a sum of hafnium and aluminum.

When the dopant is silicon (Si), the ferroelectric material film may contain 2 to 10 at % of silicon. When the dopant is yttrium (Y), the ferroelectric material film may contain 2 to 10 at % yttrium. When the dopant is gadolinium (Gd), the ferroelectric material film may contain 1 to 7 at % gadolinium. When the dopant is zirconium (Zr), the ferroelectric material film may contain 50 to 80 at % zirconium.

The paraelectric material film may have paraelectric properties. The paraelectric material film may include, for example, at least one of silicon oxide or metal oxide having a high dielectric constant. Although the metal oxide contained in the paraelectric material film may include, for example, at least one of hafnium oxide, zirconium oxide or aluminum oxide. However, the present disclosure is not limited thereto.

The ferroelectric material film and the paraelectric material film may include the same material. The ferroelectric material film may have ferroelectric properties, but the paraelectric material film may not have the ferroelectric properties. For example, when each of the ferroelectric material film and the paraelectric material film includes hafnium oxide, a crystal structure of hafnium oxide contained in the ferroelectric material film is different from a crystal structure of hafnium oxide contained in the paraelectric material film.

The ferroelectric material film may have a thickness sized to exhibit ferroelectric properties. Although the thickness of the ferroelectric material film may be, for example, in a range of 0.5 to 10 nm, the present disclosure is not limited thereto. Because a critical thickness exhibiting the ferroelectric properties may vary based on a type of the ferroelectric material, the thickness of the ferroelectric material film may vary depending on the type of the ferroelectric material.

In an example, each of the first to third gate insulating layers 121, 122, and 123 may include one ferroelectric material film. In another example, each of the first to third gate insulating layers 121, 122, and 123 may include a plurality of ferroelectric material films spaced apart from each other. Each of the first to third gate insulating layers 121, 122, and 123 may have a stacked film structure in which a plurality of ferroelectric material films and a plurality of paraelectric material films are alternately stacked on top of each other.

The first etching stop layer 160 may be disposed on a sidewall facing in the first horizontal direction DR1 of each of the first to third gate spacers 111, 112, and 113. The first etching stop layer 160 may be disposed on the upper surface of each of the first and second source/drain regions SD1 and SD2. The first etching stop layer 160 may be disposed on a sidewall facing in the second horizontal direction DR2 of each of the first and second source/drain regions SD1 and SD2. The first etching stop layer 160 may be formed conformally. The first etching stop layer 160 may include at least one of aluminum oxide, aluminum nitride, hafnium oxide, zirconium oxide, silicon oxide, silicon nitride, silicon oxynitride, or a low dielectric constant material.

The first capping pattern 131 may extend in the second horizontal direction DR2 and be disposed on each of the first gate spacer 111, the first gate insulating layer 121, and the first gate electrode G1. The second capping pattern 132 may extend in the second horizontal direction DR2 and be disposed on each of the second gate spacer 112, the second gate insulating layer 122, and the second gate electrode G2. The third capping pattern 133 may extend in the second horizontal direction DR2 and be disposed on each of the third gate spacer 113, the third gate insulating layer 123, and the third gate electrode G3. A lower surface of each of the first to third capping patterns 131, 132, and 133 may contact the first etching stop layer 160. However, the present disclosure is not limited thereto. In some embodiments, a sidewall of each of the first to third capping patterns 131, 132, and 133 may contact the first etching stop layer 160. Each of the first to third capping patterns 131, 132, and 133 may include, for example, at least one of silicon nitride (SiN), silicon oxynitride (SiON), silicon oxide (SiO₂), silicon carbonitride (SiCN), silicon oxycarbonitride (SiOCN), or combinations thereof. However, the present disclosure is not limited thereto.

The first upper interlayer insulating layer 170 may be disposed on the first etching stop layer 160. The first upper interlayer insulating layer 170 may be disposed on a sidewall of each of the first to third capping patterns 131, 132, and 133. The first upper interlayer insulating layer 170 may cover the first and second source/drain regions SD1 and SD2 while being disposed on the field insulating layer 105. An upper surface of the first upper interlayer insulating layer 170 may be coplanar with an upper surface of each of the first to third capping patterns 131, 132, and 133. The first upper interlayer insulating layer 170 may include at least one of silicon oxide, silicon nitride, silicon oxynitride, or a low dielectric constant material.

The first sacrificial pattern 141 may be disposed under the first source/drain region SD1. An upper surface of the first sacrificial pattern 141 may contact the lower surface of the first source/drain region SD1. Each of both opposing sidewalls in the first horizontal direction DR1 of the first sacrificial pattern 141 may contact the insulating pattern 101 and the lower interlayer insulating layer 100. A lower surface of the first sacrificial pattern 141 may contact the lower interlayer insulating layer 100. However, the present disclosure is not limited thereto. In some embodiments, the lower surface of the first sacrificial pattern 141 may contact the insulating pattern 101.

The upper surface of the first sacrificial pattern 141 may be positioned at a lower vertical level than that of the upper surface of the insulating pattern 101. Although not shown, the upper surface of the first sacrificial pattern 141 may be positioned at a lower vertical level than that of the upper surface of the field insulating layer 105. A width in the first horizontal direction DR1 of the first sacrificial pattern 141 may be smaller than a width in the first horizontal direction DR1 of the first source/drain region SD1. The first sacrificial pattern 141 may include silicon germanium (SiGe).

The lower source/drain contact BCA may be disposed under the second source/drain region SD2. The lower source/drain contact BCA may penetrate the lower interlayer insulating layer 100 and the insulating pattern 101 in the vertical direction DR3 so as to be electrically connected to the second source/drain region SD2. The lower source/drain contact BCA may include a first portion BCA_1 and a second portion BCA_2 disposed under the first portion BCA_1.

The first portion BCA_1 of the lower source/drain contact BCA may overlap the insulating pattern 101 in the first horizontal direction DR1. The first portion BCA_1 of the lower source/drain contact BCA may be spaced apart from the insulating pattern 101 in the first horizontal direction DR1. The first portion BCA_1 of the lower source/drain contact BCA may overlap the field insulating layer 105 in the second horizontal direction DR2. The first portion BCA_1 of the lower source/drain contact BCA may be spaced apart from the field insulating layer 105 in the second horizontal direction DR2.

An upper surface of the second portion BCA_2 of the lower source/drain contact BCA may contact a lower surface of the first portion BCA_1 of the lower source/drain contact BCA. Each of both opposing sidewalls in the first horizontal direction DR1 of the second portion BCA_2 of the lower source/drain contact BCA may contact the lower interlayer insulating layer 100 and the insulating pattern 101. Each of both opposing sidewalls in the second horizontal direction DR2 of the second portion BCA_2 of the lower source/drain contact BCA may be in contact with the lower interlayer insulating layer 100 and the field insulating layer 105.

A width in the first horizontal direction DR1 of the second portion BCA_2 of the lower source/drain contact BCA may be larger than a width in the first horizontal direction DR1 of the first portion BCA_1 of the lower source/drain contact BCA. Additionally, a width in the second horizontal direction DR2 of the second portion BCA_2 of the lower source/drain contact BCA may be larger than a width in the second horizontal direction DR2 of the first portion BCA_1 of the lower source/drain contact BCA. At least a portion of the upper surface of the second portion BCA_2 of the lower source/drain contact BCA may be in contact with the insulating pattern 101. However, the present disclosure is not limited thereto. The lower source/drain contact BCA may be formed as a single film. However, the present disclosure is not limited thereto. In some embodiments, the lower source/drain contact BCA may be formed as a multilayer structure. The lower source/drain contact BCA may include a conductive material.

The lower silicide layer BSL may be disposed between the lower source/drain contact BCA and the second source/drain region SD2. The lower silicide layer BSL may be disposed along an interface between the lower source/drain contact BCA and the second source/drain region SD2. The lower silicide layer BSL may include, for example, a metal silicide material. The lower silicide layer BSL may overlap the insulating pattern 101 in the first horizontal direction DR1. Additionally, the lower silicide layer BSL may overlap the field insulating layer 105 in the second horizontal direction DR2.

The first insulating liner layer 151 may be disposed under the first source/drain region SD1. An upper surface of the first insulating liner layer 151 may be in contact with the lower surface of the first source/drain region SD1. The upper surface of the first insulating liner layer 151 may be coplanar with the upper surface of the first sacrificial pattern 141. Although not shown, the upper surface of the first insulating liner layer 151 may be positioned at a lower vertical level than that of the upper surface of the field insulating layer 105. For example, a lower surface of the first insulating liner layer 151 may be positioned at a higher vertical level than that of the lower surface of the first sacrificial pattern 141. The lower surface of the first insulating liner layer 151 may contact the insulating pattern 101. However, the present disclosure is not limited thereto. In some embodiments, the lower surface of the first insulating liner layer 151 may contact the lower interlayer insulating layer 100.

The first insulating liner layer 151 may surround a portion of the sidewall of the first sacrificial pattern 141. For example, an inner sidewall facing in the first horizontal direction DR1 of the first insulating liner layer 151 may contact the first sacrificial pattern 141. Although not shown, an inner sidewall facing in the second horizontal direction DR2 of the first insulating liner layer 151 may contact the first sacrificial pattern 141. For example, an outer sidewall facing in the first horizontal direction DR1 of the first insulating liner layer 151 may contact the insulating pattern 101. Although not shown, an outer sidewall facing in the second horizontal direction DR2 of the first insulating liner layer 151 may contact the field insulating layer 105.

A slope of the outer sidewall facing in the first horizontal direction DR1 of the first insulating liner layer 151 may be continuous with a slope of the sidewall facing in the first horizontal direction DR1 of the first source/drain region SD1 (e.g., the outer sidewall facing in the first horizontal direction DR1 of the first insulating liner layer 151 may continuously contact a slope of the sidewall facing in the first horizontal direction DR1 of the first source/drain region SD1, or the outer sidewall facing in the first horizontal direction DR1 of the first insulating liner layer 151 may have a profile complementary to a profile of the sidewall facing in the first horizontal direction DR1 of the first source/drain region SD1 such that they are in contact or offset by a fixed distance). The first insulating liner layer 151 does not overlap with each of the first plurality of nanosheets NW1, the second plurality of nanosheets NW2, the first gate electrode G1, and the second gate electrode G2 in the vertical direction DR3.

The second insulating liner layer 152 may be disposed under the second source/drain region SD2. An upper surface of the second insulating liner layer 152 may be in contact with the lower surface of the second source/drain region SD2. The upper surface of the second insulating liner layer 152 may be coplanar with the upper surface of the lower source/drain contact BCA. That is, the upper surface of the second insulating liner layer 152 may be coplanar with the upper surface of the first portion BCA_1 of the lower source/drain contact BCA. The upper surface of the second insulating liner layer 152 may be positioned at a lower vertical level than that of the upper surface of the field insulating layer 105. A lower surface of the second insulating liner layer 152 may contact the upper surface of the second portion BCA_2 of the lower source/drain contact BCA. The upper surface of the second insulating liner layer 152 may not contact the lower silicide layer BSL. However, the present disclosure is not limited thereto. In some embodiments, at least a portion of the upper surface of the second insulating liner layer 152 may be in contact with the lower silicide layer BSL.

The second insulating liner layer 152 may surround a sidewall of the first portion BCA_1 of the lower source/drain contact BCA. For example, an inner sidewall facing in the first horizontal direction DR1 of the second insulating liner layer 152 may contact the first portion BCA_1 of the lower source/drain contact BCA. Additionally, an inner sidewall facing in the second horizontal direction DR2 of the second insulating liner layer 152 may contact the first portion BCA_1 of the lower source/drain contact BCA. For example, an outer sidewall facing in the first horizontal direction DR1 of the second insulating liner layer 152 may contact the insulating pattern 101. An outer sidewall in the second horizontal direction DR2 of the second insulating liner layer 152 may be in contact with the field insulating layer 105.

A slope of the outer sidewall facing in the first horizontal direction DR1 of the second insulating liner layer 152 may be continuous with a slope of the sidewall facing in the first horizontal direction DR1 of the second source/drain region SD2. The second insulating liner layer 152 does not overlap with each of the second plurality of nanosheets NW2, the third plurality of nanosheets NW3, the second gate electrode G2, and the third gate electrode G3 in the vertical direction DR3.

The first insulating liner layer 151 and the second insulating liner layer 152 may include the same material. Each of the first and second insulating liner layers 151 and 152 may include a different material from each of the insulating pattern 101 and the lower interlayer insulating layer 100. Each of the first and second insulating liner layers 151 and 152 may include an insulating material having a low dielectric constant. For example, each of the first and second insulating liner layers 151 and 152 may include silicon nitride (SiN), silicon oxynitride (SiON), silicon carbonitride (SiCN), or silicon oxycarbonitride (SiOCN). However, the present disclosure is not limited thereto.

The upper source/drain contact UCA may be disposed between the first gate electrode G1 and the second gate electrode G2. The upper source/drain contact UCA may be disposed in a top of the first source/drain region SD1. The upper source/drain contact UCA may penetrate through the first upper interlayer insulating layer 170 and the first etching stop layer 160 in the vertical direction DR3 into the first source/drain region SD1. The upper source/drain contact UCA may be electrically connected to the first source/drain region SD1. In FIG. 2, the upper source/drain contact UCA is shown as being formed as a single film. However, the present disclosure is not limited thereto. In some embodiments, the upper source/drain contact UCA may be formed as a multilayer structure.

An upper surface of the upper source/drain contact UCA may be coplanar with the upper surface of the first upper interlayer insulating layer 170. However, the present disclosure is not limited thereto. In some embodiments, the upper surface of the upper source/drain contact UCA may be positioned at a higher vertical level than that of the upper surface of the first upper interlayer insulating layer 170. The upper source/drain contact UCA may include a conductive material.

The upper silicide layer USL may be disposed between the upper source/drain contact UCA and the first source/drain region SD1. The upper silicide layer USL may be disposed along an interface between the upper source/drain contact UCA and the first source/drain region SD1. The upper silicide layer USL may include a metal silicide material.

The gate contact CB may be disposed on a top of the second gate electrode G2. The gate contact CB may penetrate the second capping pattern 132 in the vertical direction DR3 so as to be connected to the second gate electrode G2. In FIG. 3, the gate contact CB is shown as being formed as a single film. However, the present disclosure is not limited thereto. In some embodiments, the gate contact CB may be formed as a multilayer structure. An upper surface of the gate contact CB may be coplanar with each of the upper surface of the upper source/drain contact UCA and the upper surface of the first upper interlayer insulating layer 170. However, the present disclosure is not limited thereto. The gate contact CB may include a conductive material.

The second etching stop layer 180 may be disposed on an upper surface of each of the upper source/drain contact UCA, the first to third capping patterns 131, 132, and 133, and the first upper interlayer insulating layer 170. In FIGS. 2 to 4, the second etching stop layer 180 is shown as being formed as a single film. However, the present disclosure is not limited thereto. In some embodiments, the second etching stop layer 180 may be formed as a multilayer structure. The second etching stop layer 180 may include at least one of aluminum oxide, aluminum nitride, hafnium oxide, zirconium oxide, silicon oxide, silicon nitride, silicon oxynitride, or a low dielectric constant material.

The second upper interlayer insulating layer 190 may be disposed on the second etching stop layer 180. The second upper interlayer insulating layer 190 may include at least one of silicon oxide, silicon nitride, silicon oxynitride, or a low dielectric constant material.

The first via V1 may penetrate through the second upper interlayer insulating layer 190 and the second etching stop layer 180 in the vertical direction DR3 so as to be connected to the upper source/drain contact UCA. The second via V2 may penetrate the second upper interlayer insulating layer 190 and the second etching stop layer 180 in the vertical direction DR3 so as to be connected to the gate contact CB. In FIG. 2 and FIG. 3, each of the first via V1 and the second via V2 is shown as being formed as a single film. However, the present disclosure is not limited thereto. In some embodiments, each of the first via V1 and the second via V2 may be formed as a multilayer structure. Each of the first via V1 and the second via V2 may include a conductive material.

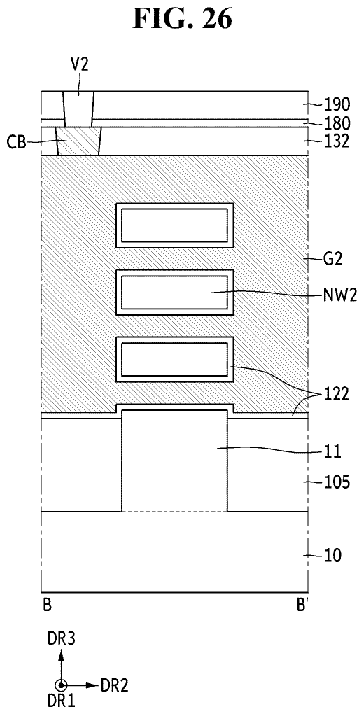

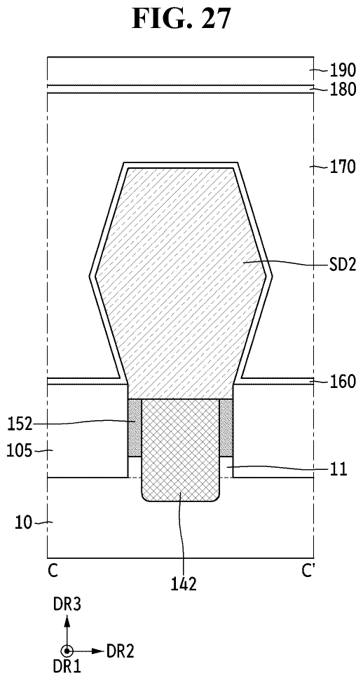

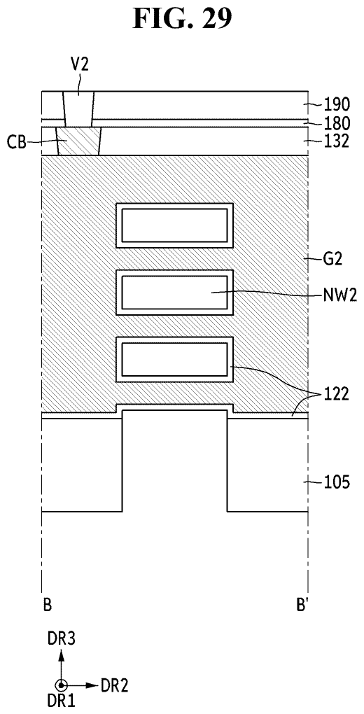

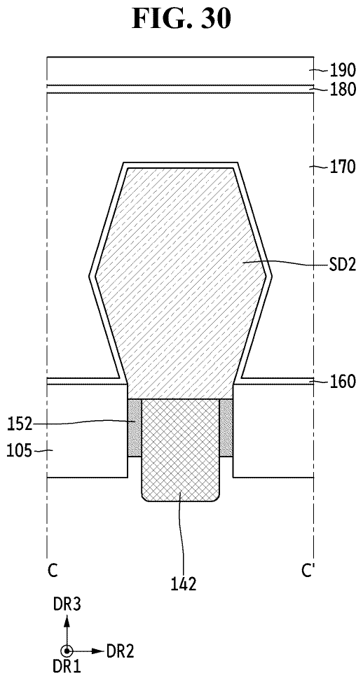

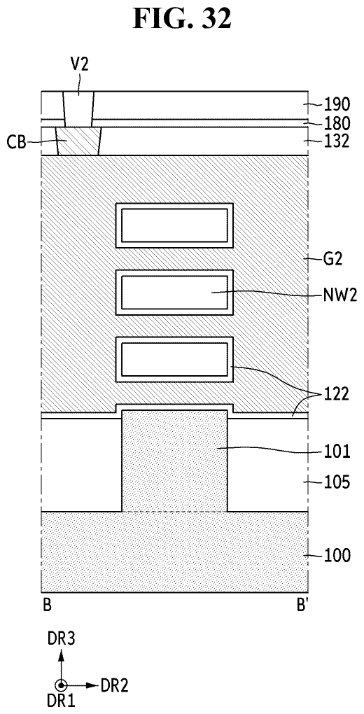

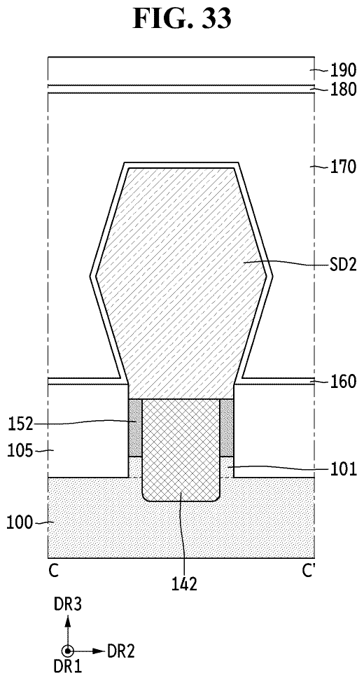

Hereinafter, a method for fabricating a semiconductor device according to some embodiments of the present disclosure is described with reference to FIGS. 2 to 37.

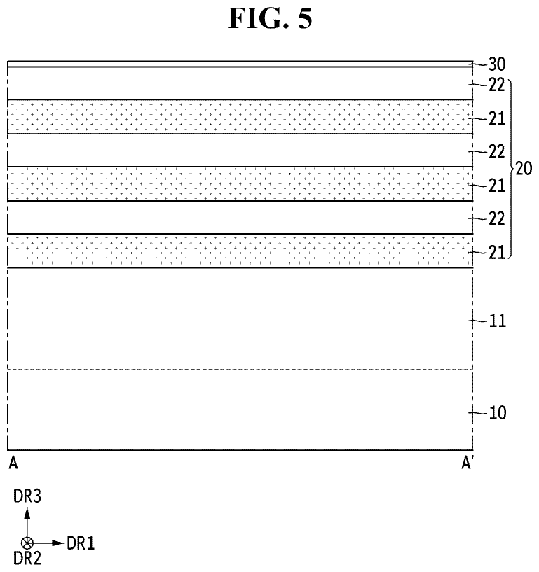

FIGS. 5 to 37 are diagrams of intermediate structures corresponding to intermediate steps of a method for fabricating a semiconductor device according to some embodiments of the present disclosure.

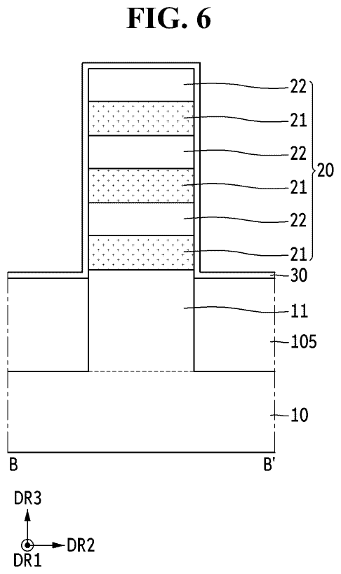

Referring to FIG. 5 and FIG. 6, the substrate 10 may be provided. The substrate 10 may be a silicon substrate or a silicon-on-insulator (SOI). Alternatively, the substrate 10 may include silicon germanium, silicon germanium on insulator (SGOI), indium antimonide, lead telluride, indium arsenide, indium phosphide, gallium arsenide, or gallium antimonide. However, the present disclosure is not limited thereto.

Subsequently, a stack structure 20 may be formed on the upper surface of the substrate 10. The stack structure 20 may include first semiconductor layers 21 and second semiconductor layers 22 alternately stacked on top of each other while being disposed on the upper surface of the substrate 10. For example, the first semiconductor layer 21 may be formed as the lowermost layer of the stack structure 20, and the second semiconductor layer 22 may be formed as the uppermost layer of the stack structure 20. However, the present disclosure is not limited thereto. In some embodiments, the first semiconductor layer 21 may be formed as the uppermost layer of the stack structure 20. The first semiconductor layer 21 may include, for example, silicon germanium (SiGe). The second semiconductor layer 22 may include, for example, silicon (Si).

Subsequently, a portion of the stack structure 20 may be etched. When the stack structure 20 is etched, a portion of the substrate 10 may be etched. In this etching process, the active pattern 11 may be defined under the stack structure 20 and on the upper surface of the substrate 10. The active pattern 11 may protrude from the upper surface of the substrate 10 in the vertical direction DR3. The active pattern 11 may extend in the first horizontal direction DR1.

Subsequently, the field insulating layer 105 may be formed on the upper surface of the substrate 10. The field insulating layer 105 may surround the sidewall of the active pattern 11. The upper surface of the active pattern 11 may be positioned at a higher vertical level than that of the upper surface of the field insulating layer 105. Subsequently, a pad oxidation layer 30 may be formed to cover the upper surface of the field insulating layer 105, an exposed sidewall of each of the active patterns 11, and a sidewall and an upper surface of the stack structure 20. The pad oxidation layer 30 may be formed conformally. The pad oxidation layer 30 may include, for example, silicon oxide (SiO₂).

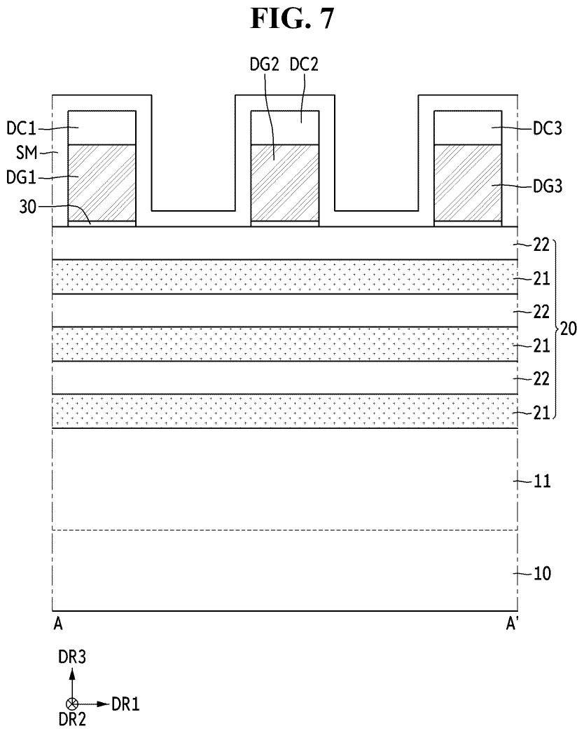

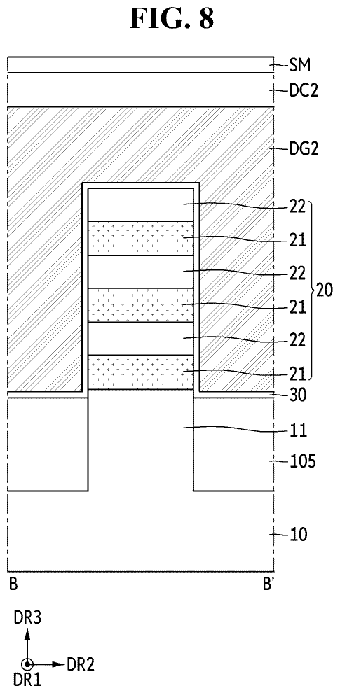

Referring to FIG. 7 and FIG. 8, on the stack structure 20 and the field insulating layer 105, first to third dummy gates DG1, DG2, and DG3 and first to third dummy capping patterns DC1, DC2, and DC3 extending in the second horizontal direction DR2 may be formed on the pad oxidation layer 30. Specifically, the second dummy gate DG2 may be spaced apart from the first dummy gate DG1 in the first horizontal direction DR1. The third dummy gate DG3 may be spaced apart from the second dummy gate DG2 in the first horizontal direction DR1. The first dummy capping pattern DC1 may be disposed on the first dummy gate DG1. The second dummy capping pattern DC2 may be disposed on the second dummy gate DG2. The third dummy capping pattern DC3 may be disposed on the third dummy gate DG3. While the first to third dummy gates DG1, DG2, and DG3 and the first to third dummy capping patterns DC1, DC2, and DC3 are formed, a remaining portion of the pad oxidation layer 30 other than a portion thereof overlapping each of the first to third dummy gates DG1, DG2 and DG3 in the vertical direction DR3 on the substrate 10 may be removed.

Next, a spacer material layer SM may be formed to cover a sidewall of each of the first to third dummy gates DG1, DG2, and DG3, a sidewall and an upper surface of each of the first to third dummy capping patterns DC1, DC2, and DC3, an exposed sidewall and upper surface of the stack structure 20 and the upper surface of the field insulating layer 105. The spacer material layer SM may be formed conformally. The spacer material layer SM may include, for example, at least one of silicon nitride (SiN), silicon oxynitride (SiON), silicon oxide (SiO₂), silicon oxycarbonitride (SiOCN), silicon boron nitride (SiBN), silicon oxyboron nitride (SiOBN), silicon oxycarbide (SiOC), or combinations thereof. However, the present disclosure is not limited thereto.

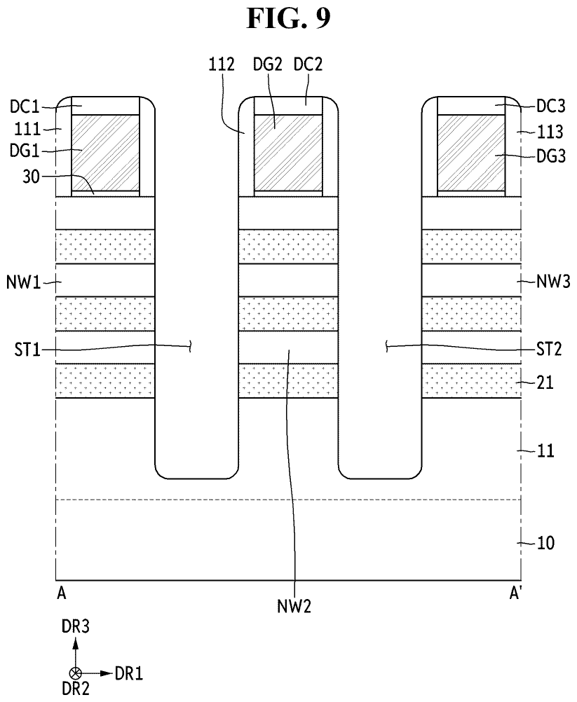

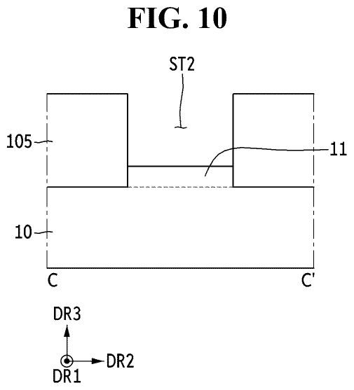

Referring to FIG. 9 and FIG. 10, using the first to third dummy gates DG1, DG2, and DG3 and the first to third dummy capping patterns DC1, DC2, and DC3 as masks, the stack structure (20 in FIG. 7) may be etched to form first and second source/drain trenches ST1 and ST2. The first source/drain trench ST1 may be formed between the first dummy gate DG1 and the second dummy gate DG2. The second source/drain trench ST2 may be formed between the second dummy gate DG2 and the third dummy gate DG3. A lower surface of the second source/drain trench ST2 may be positioned at a lower vertical level than that of the upper surface of the field insulating layer 105. Although not shown, a bottom surface of the first source/drain trench ST1 may be positioned at a lower vertical level than that of the upper surface of the field insulating layer 105.

While the first and second source/drain trenches ST1 and ST2 are formed, a portion of the spacer material layer (SM in FIG. 7) formed on the upper surface of each of the first to third dummy capping patterns DC1, DC2, and DC3, and a portion of each of the first to third dummy capping patterns DC1, DC2, and DC3 may be removed. Portions of the spacer material layer (SM in FIG. 7) remaining on sidewalls of the first to third dummy capping patterns DC1, DC2, and DC3 and the first to third dummy gates DG1, DG2, and DG3 may be defined as the third gate spacers 111, 112, and 113, respectively.

After the first and second source/drain trenches ST1 and ST2 are formed, the second semiconductor layer (22 in FIG. 7) remaining under the first dummy gate DG1 on the active pattern 11 may be defined as the first plurality of nanosheets NW1.

After the first and second source/drain trenches ST1 and ST2 are formed, portions of the second semiconductor layer (22 in FIG. 7) remaining under the second dummy gate DG2 and on the active pattern 11 may be defined as the second plurality of nanosheets NW2. After the first and second source/drain trenches ST1 and ST2 are formed, portions of the second semiconductor layer (22 in FIG. 7) remaining under the third dummy gate DG3 and on the active pattern 11 may be defined as the third plurality of nanosheets NW3.

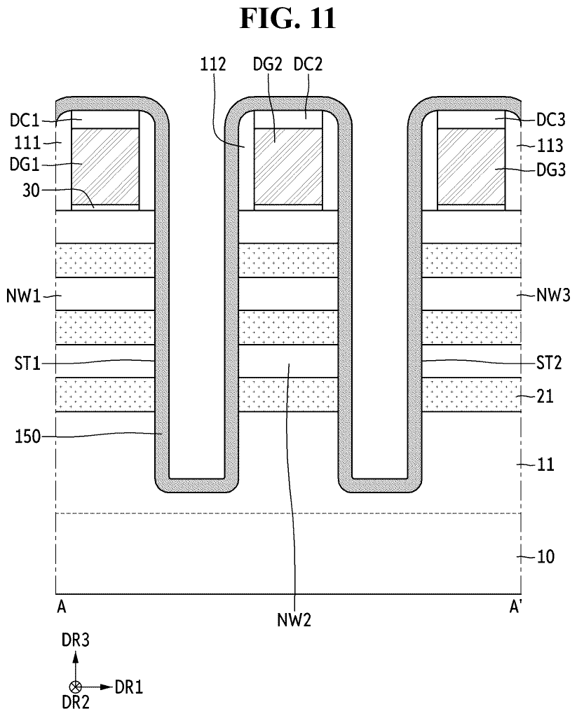

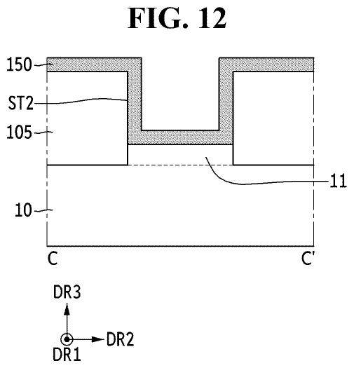

Referring to FIG. 11 and FIG. 12, the insulating material layer 150 may be formed on the sidewall and the bottom surface of each of the first and second source/drain trenches ST1 and ST2. For example, the insulating material layer 150 may be formed on the upper surface of the field insulating layer 105, the sidewall of each of the first to third gate spacers 111, 112, and 113, and the upper surface of each of the first to third dummy capping patterns DC1, DC2, and DC3. For example, the insulating material layer 150 may be formed conformally. The insulating material layer 150 may include an insulating material having a low dielectric constant. For example, the insulating material layer 150 may include silicon nitride (SiN), silicon oxynitride (SiON), silicon carbonitride (SiCN), or silicon oxycarbonitride (SiOCN). However, the present disclosure is not limited thereto.

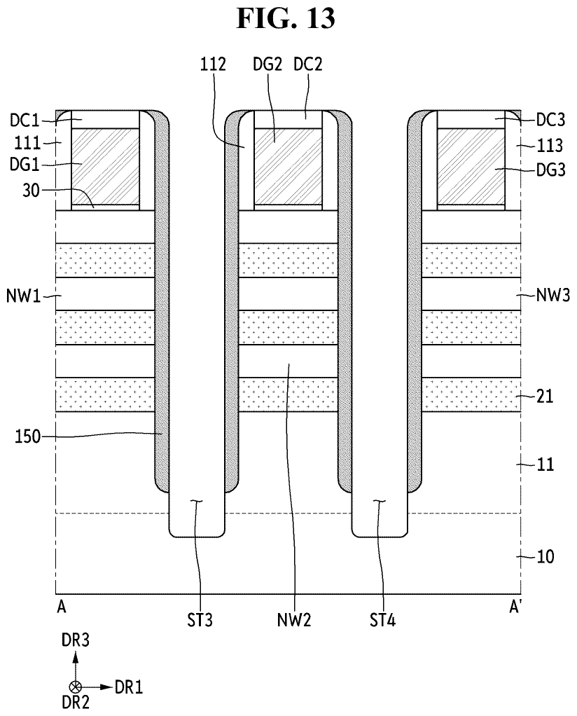

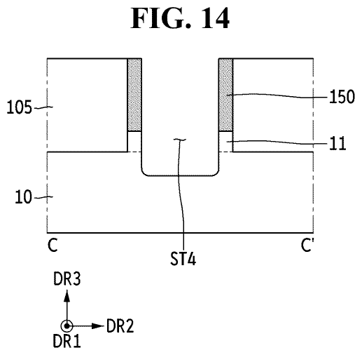

Referring to FIG. 13 and FIG. 14, third and fourth source/drain trenches ST3 and ST4 may be formed inside the first and second source/drain trenches (ST1 and ST2 in FIG. 11), respectively. For example, a portion of each of the insulating material layer 150, the active pattern 11, and the substrate 10 formed on the bottom surface of the first source/drain trench (ST1 in FIG. 11) may be etched to form the third source/drain trench ST3 extending into the interior of the substrate 10. In addition, a portion of each of the insulating material layer 150, the active pattern 11, and the substrate 10 formed on the bottom surface of the second source/drain trench (ST2 in FIG. 11 and FIG. 12) may be etched to form the fourth source/drain trench ST4 extending into the interior of the substrate 10.

When the third and fourth source/drain trenches ST3 and ST4 are formed, a portion of the insulating material layer 150 formed on the upper surface of the field insulating layer 105 and the upper surface of each of the first to third dummy capping patterns DC1, DC2, and DC3 may be etched. A portion of the insulating material layer 150 may remain on each of both opposing sidewalls in the first horizontal direction DR1 of each of the third and fourth source/drain trenches ST3 and ST4. Additionally, a portion of the insulating material layer 150 may remain on each of both opposing sidewalls in the second horizontal direction DR2 of each of the third and fourth source/drain trenches ST3 and ST4.

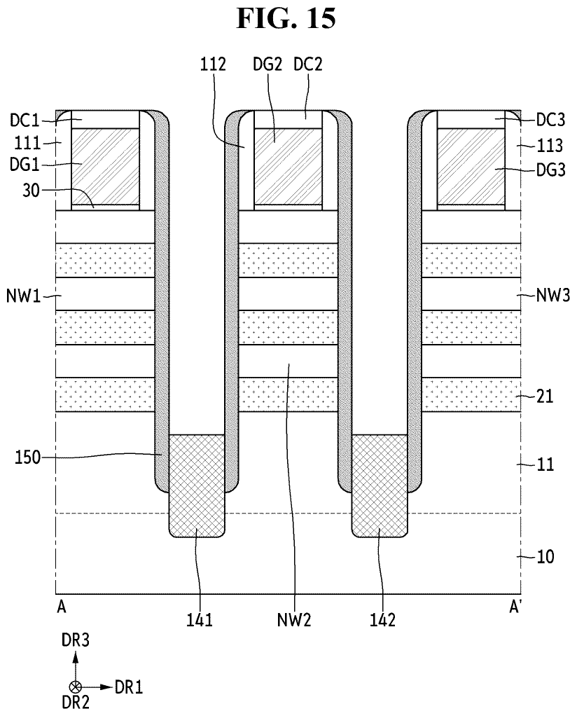

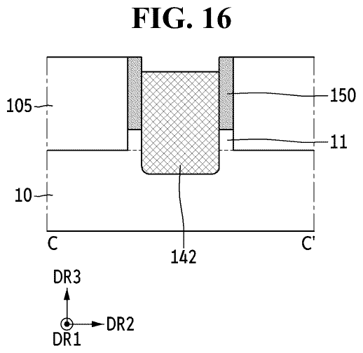

Referring to FIGS. 15 and 16, a first sacrificial pattern 141 may be formed inside the third source/drain trench (ST3 in FIG. 13). Additionally, a second sacrificial pattern 142 may be formed inside the fourth source/drain trench (ST4 in FIG. 13 and FIG. 14). An upper surface of each of the first and second sacrificial patterns 141 and 142 may be positioned at a lower vertical level than that of the uppermost surface of the active pattern 11. The upper surface of each of the first and second sacrificial patterns 141 and 142 may be positioned at a lower vertical level than that of the upper surface of the field insulating layer 105. A lower surface of each of the first and second sacrificial patterns 141 and 142 may be positioned at a lower vertical level than that of the lower surface of the insulating material layer 150. At least a portion of each of both opposing sidewalls in the first horizontal direction DR1 of each of the first and second sacrificial patterns 141 and 142 may be in contact with the insulating material layer 150. At least a portion of each of both opposing sidewalls in the second horizontal direction DR2 of each of the first and second sacrificial patterns 141 and 142 may be in contact with the insulating material layer 150.

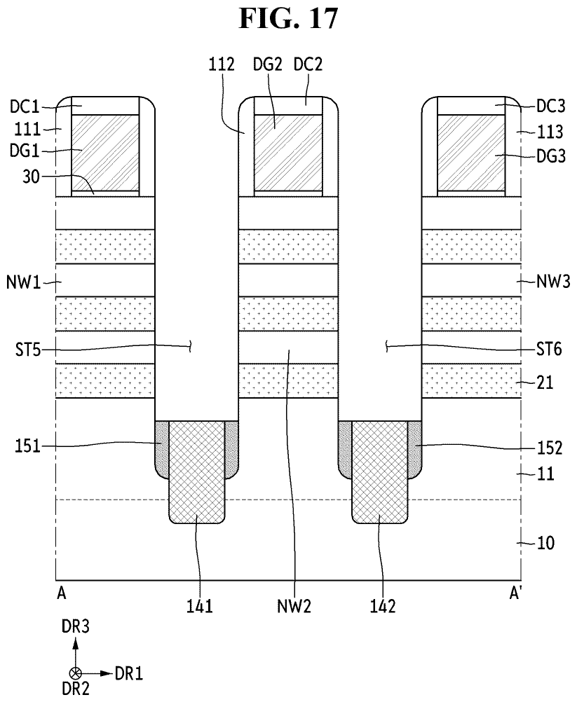

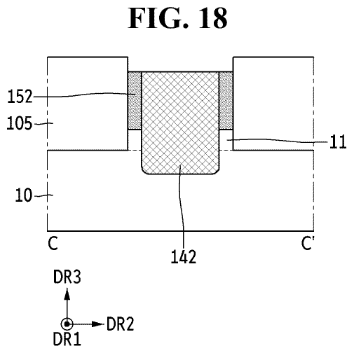

Referring to FIG. 17 and FIG. 18, a portion of the insulating material layer (150 in FIG. 15 and FIG. 16) not covered with the upper surface of each of the first and second sacrificial patterns 141 and 142 may be etched to form each of fifth and sixth source/drain trenches ST5 and ST6. For example, a portion of the insulating material layer (150 in FIG. 15) not covered with the upper surface of the first sacrificial pattern 141 may be etched to form the fifth source/drain trench ST5. Additionally, a portion of the insulating material layer 150 in FIGS. 15 and 16 not covered with the upper surface of the second sacrificial pattern 142 may be etched to form a sixth source/drain trench ST6. After the fifth source/drain trench ST5 is formed, the remaining portion of the insulating material layer (150 in FIG. 15) may be defined as the first insulating liner layer 151. Additionally, after the sixth source/drain trench ST6 is formed, the remaining portion of the insulating material layer (150 in FIGS. 15 and 16) may be defined as the second insulating liner layer 152.

An upper surface of each of the first and second insulating liner layers 151 and 152 may be positioned at a lower vertical level than that of the uppermost surface of the active pattern 11. The upper surface of the second insulating liner layer 152 may be positioned at a lower vertical level than that of the upper surface of the field insulating layer 105. Although not shown, the upper surface of the first insulating liner layer 151 may be positioned at a lower vertical level than that of the upper surface of the field insulating layer 105. The upper surface of the first insulating liner layer 151 may be coplanar with the upper surface of the first sacrificial pattern 141. Additionally, the upper surface of the second insulating liner layer 152 may be coplanar with the upper surface of the second sacrificial pattern 142.

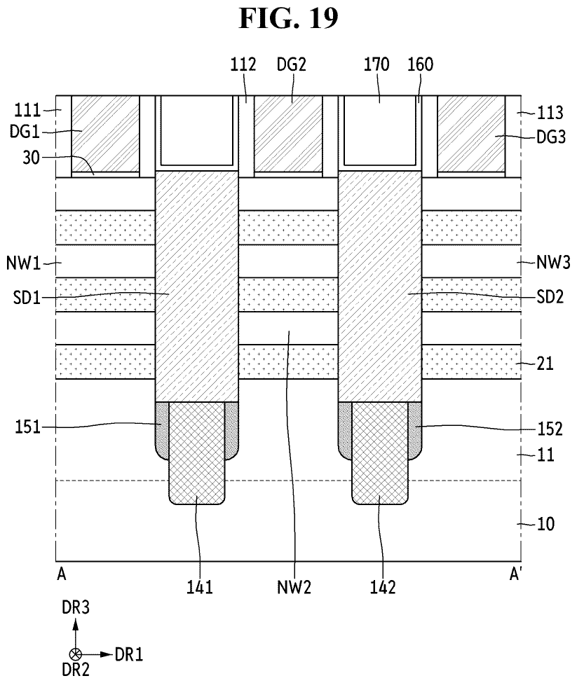

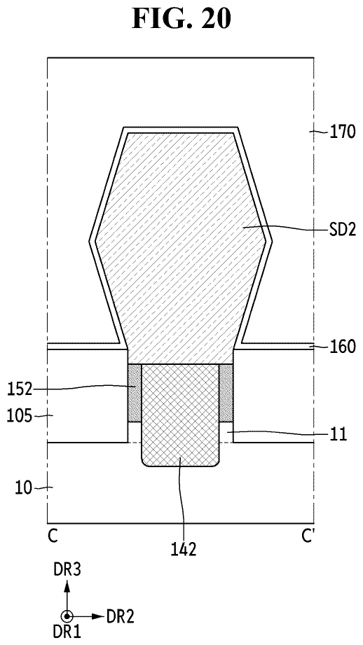

Referring to FIG. 19 and FIG. 20, the first source/drain region SD1 may be formed inside the fifth source/drain trench (ST5 in FIG. 17). Additionally, the second source/drain region SD2 may be formed inside the sixth source/drain trench (ST6 in FIG. 17). The lower surface of the first source/drain region SD1 may contact each of the upper surface of the first sacrificial pattern 141 and the upper surface of the first insulating liner layer 151. Additionally, the lower surface of the second source/drain region SD2 may be in contact with each of the upper surface of the second sacrificial pattern 142 and the upper surface of the second insulating liner layer 152.

Subsequently, the first etching stop layer 160 may be formed on an exposed upper surface of the field insulating layer 105, an exposed sidewalls of each of the first to third gate spacers 111, 112, and 113, an exposed upper surface of each of the first to third dummy capping patterns (DC1, DC2, and DC3 in FIG. 17), and an exposed surface of each of the first and second source/drain regions SD1 and SD2. The first etching stop layer 160 may be formed conformally. Subsequently, the first upper interlayer insulating layer 170 may be formed on the first etching stop layer 160. Subsequently, the upper surface of each of the first to third dummy gates DG1, DG2, and DG3 may be exposed through a planarization process.

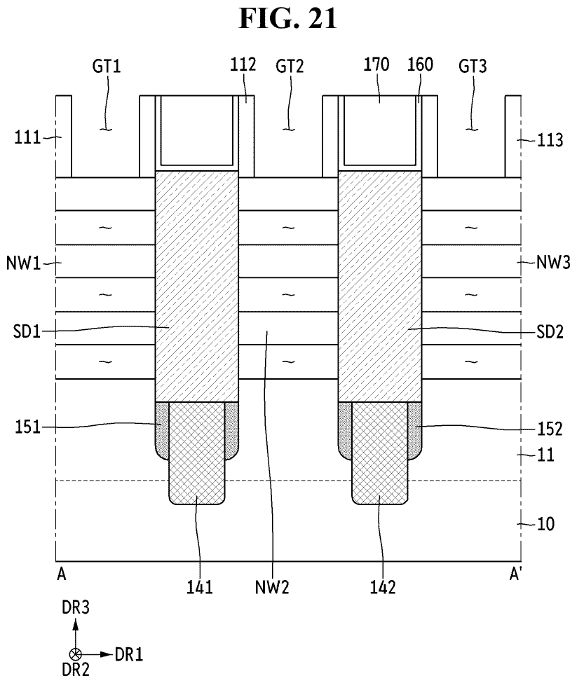

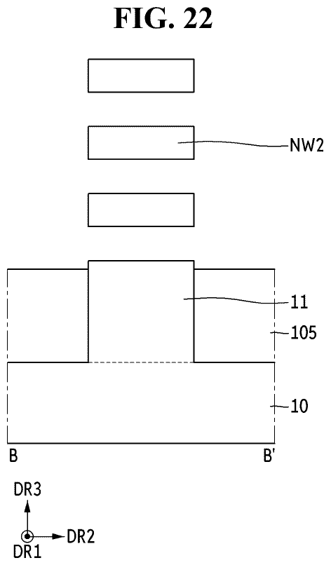

Referring to FIG. 21 and FIG. 22, each of the first to third dummy gates (DG1, DG2, and DG3 in FIG. 19), the pad oxidation layer (30 in FIG. 19), and the first semiconductor layer (21 in FIG. 19) may be etched. A space obtained by etching the first dummy gate (DG1 in FIG. 19), the pad oxidation layer (30 in FIG. 19), and the first semiconductor layer (21 in FIG. 19) may be defined as the first gate trench GT1. A space obtained by etching the second dummy gate (DG2 in FIG. 19), the pad oxidation layer (30 in FIG. 19), and the first semiconductor layer (21 in FIG. 19) may be defined as the second gate trench GT2. A space obtained by etching the third dummy gate (DG3 in FIG. 19), the pad oxidation layer (30 in FIG. 19), and the first semiconductor layer (21 in FIG. 19) may be defined as the third gate trench GT3.

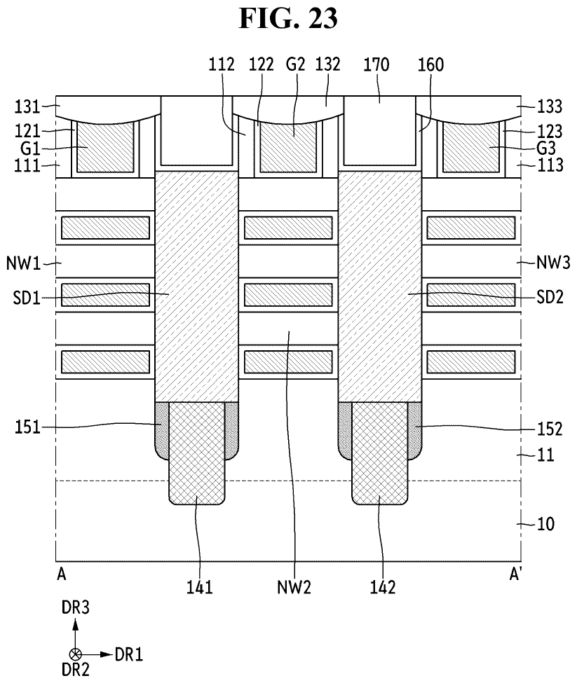

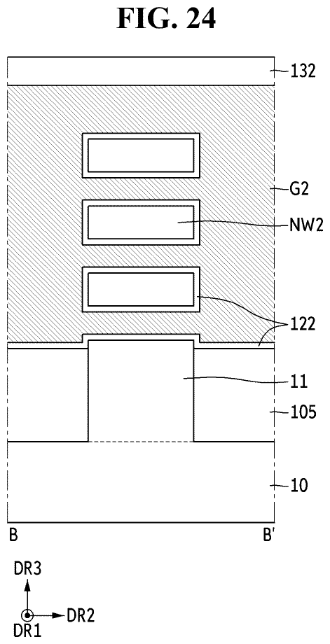

Referring to FIG. 23 and FIG. 24, the first gate insulating layer 121, the first gate electrode G1, and the first capping pattern 131 may be sequentially disposed inside the first gate trench (GT1 in FIG. 21). Additionally, the second gate insulating layer 122, the second gate electrode G2, and the second capping pattern 132 may be sequentially formed inside the second gate trench (GT2 in FIG. 21). Additionally, the third gate insulating layer 123, the third gate electrode G3, and the third capping pattern 133 may be sequentially formed inside the third gate trench (GT3 in FIG. 21).

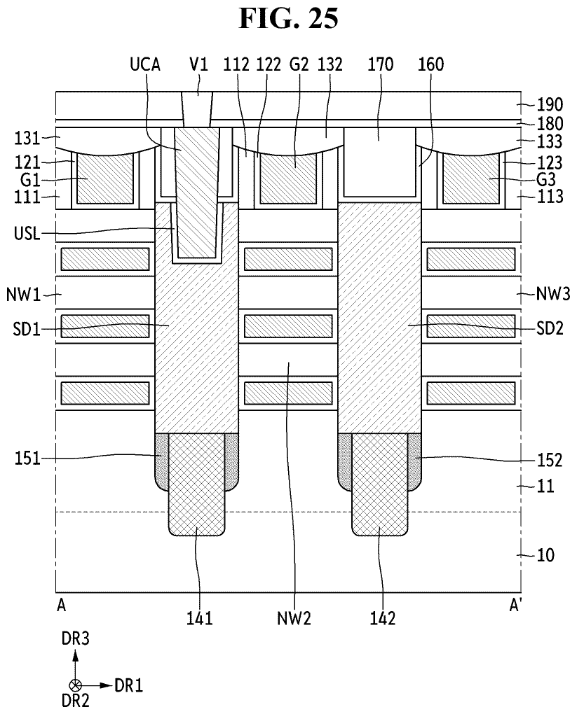

Referring to FIGS. 25 to 27, the upper source/drain contact UCA may be formed on the first source/drain region SD1. The upper source/drain contact UCA may penetrate the first upper interlayer insulating layer 170 and the first etching stop layer 160 in the vertical direction DR3 and extend into the first source/drain region SD1. Additionally, the upper silicide layer USL may be formed between the first source/drain region SD1 and the upper source/drain contact UCA. Additionally, the gate contact CB connected to the second gate electrode G2 may penetrate the second capping pattern 132 in the vertical direction DR3.

Subsequently, the second etching stop layer 180 and the second upper interlayer insulating layer 190 may be formed sequentially on the upper surface of each of the first upper interlayer insulating layer 170, the first to third capping patterns 131, 132, and 133, and the upper source/drain contact UCA. Subsequently, the first via V1 may be formed that penetrates the second etching stop layer 180 and the second upper interlayer insulating layer 190 in the vertical direction DR3 so as to contact the upper source/drain contact UCA. Additionally, the second via V2 penetrating the second etching stop layer 180 and the second upper interlayer insulating layer 190 in the vertical direction DR3 so as to contact the gate contact CB may be formed.

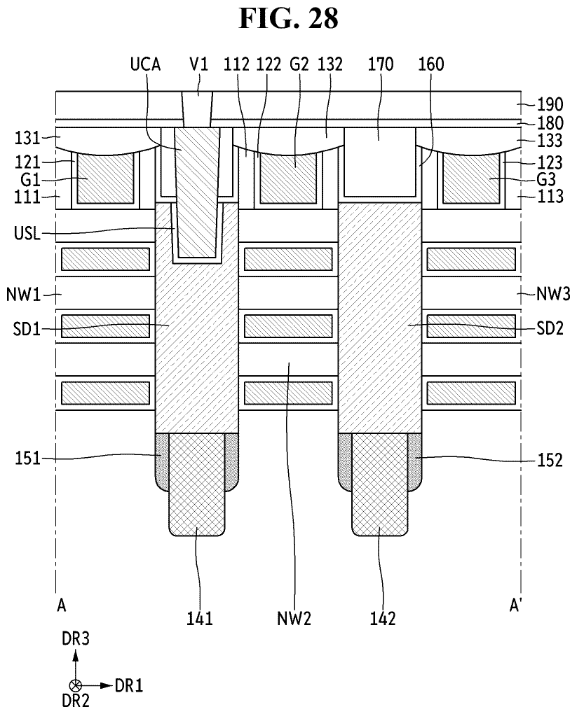

Referring to FIGS. 28 to 30, each of the substrate (10 in FIGS. 25 to 27) and the active pattern (11 in FIGS. 25 to 27) may be etched. As a result, a portion of each of the first to third gate insulating layers 121, 122, and 123, a portion of each of the first and second source/drain regions SD1 and SD2, a portion of the field insulating layer 105, a portion of each of the first and second sacrificial patterns 141 and 142 and a portion of each of the first and second insulating liner layers 151 and 152 may be exposed.

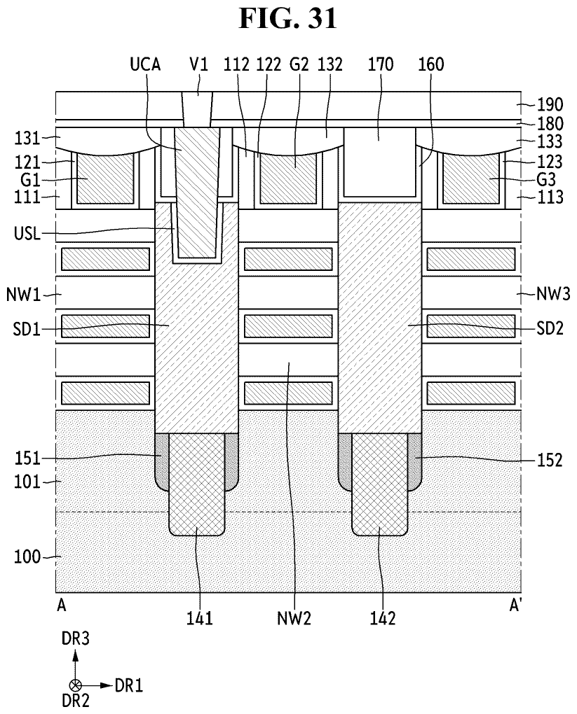

Referring to FIGS. 31 to 33, the lower interlayer insulating layer 100 and the insulating pattern 101 may be respectively formed in regions obtained by etching the substrate (10 in FIGS. 25 to 27) and the active pattern (11 in FIGS. 25 to 27). The insulating pattern 101 may be formed in the region obtained by etching the active pattern (11 in FIGS. 25 to 27). Additionally, the lower interlayer insulating layer 100 may be formed in the region obtained by etching the substrate (10 in FIG. 25 to FIG. 27).

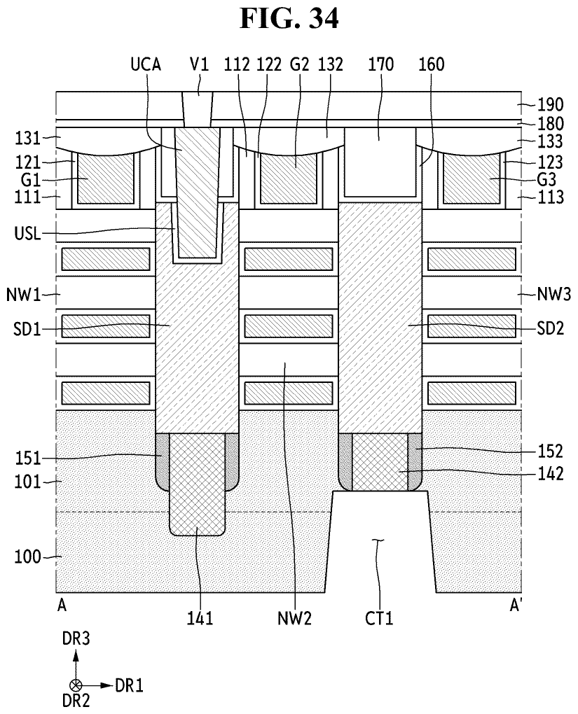

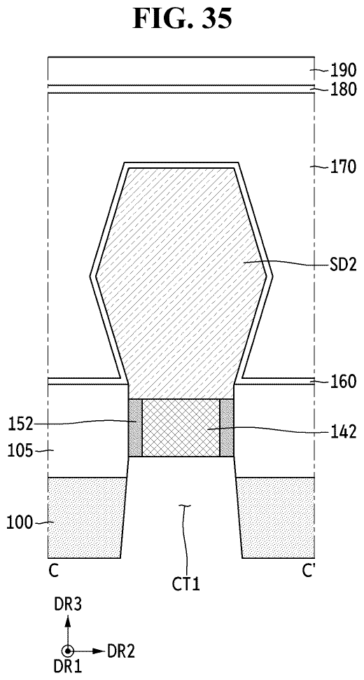

Referring to FIG. 34 and FIG. 35, the first contact trench CT1 may be formed under the second source/drain region SD2. The first contact trench CT1 may penetrate the lower interlayer insulating layer 100 and a portion of the insulating pattern 101 in the vertical direction DR3 to expose a lower surface of the second insulating liner layer 152. When the first contact trench CT1 is formed, the second insulating liner layer 152 may function as an etch stop layer. When the first contact trench CT1 is formed, a portion of the second sacrificial pattern 142 may be etched.

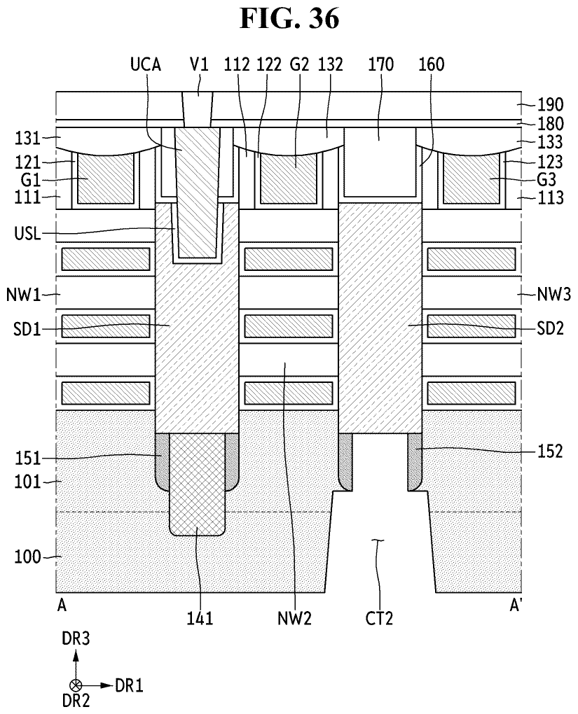

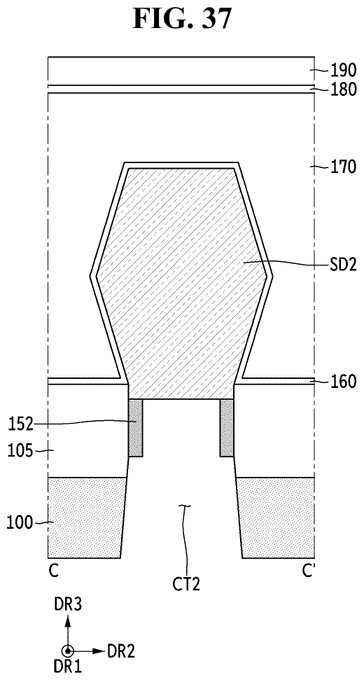

Referring to FIG. 36 and FIG. 37, the second sacrificial pattern (142 in FIG. 34 and FIG. 35) exposed through the first contact trench (CT1 in FIG. 34 and FIG. 35) may be etched to form the second contact trench CT2. A portion of the lower surface of the second source/drain region SD2 between the second insulating liner layers 152 may be exposed through the second contact trench CT2.

Referring to FIGS. 2 to 4, the lower source/drain contact BCA may be formed inside the second contact trench (CT2 in FIG. 36 and FIG. 37). The first portion BCA_1 of the lower source/drain contact BCA may be formed between the second insulating liner layer 152. Additionally, the second portion BCA_2 of the lower source/drain contact BCA may be formed on each of the lower surface of the second insulating liner layer 152 and the lower surface of the first portion BCA_1 of the lower source/drain contact BCA.

The upper surface of the first portion BCA_1 of the lower source/drain contact BCA may be coplanar with the upper surface of the second insulating liner layer 152. However, the present disclosure is not limited thereto. The upper surface of the second portion BCA_2 of the lower source/drain contact BCA may contact the lower surface of the second insulating liner layer 152. Through this fabricating process, the semiconductor device as shown in FIGS. 2 to 4 may be fabricated.

In the fabricating method of the semiconductor device according to some embodiments of the present disclosure, the second insulating liner layer 152 may be formed on the sidewall of the second sacrificial pattern 142 which is replaced with the lower source/drain contact BCA. After the substrate 10 and the active pattern 11 are etched, in a process of forming the lower interlayer insulating layer 100 and the insulating pattern 101, the sidewall of the second sacrificial pattern 142 in contact with the second insulating liner layer 152 may be prevented from oxidation. Thus, in the semiconductor device fabricating method according to some embodiments of the present disclosure, after etching the second sacrificial pattern 142, the lower source/drain contact BCA may be stably formed.

In addition, in the fabricating method of the semiconductor device according to some embodiments of the present disclosure, the second insulating liner layer 152 may perform the function of the etching stop layer in the process in which the second contact trench CT2 for forming the lower source/drain contact BCA is formed. Thus, the fabricating method of the semiconductor device according to some embodiments of the present disclosure may secure an improved process margin for forming the lower source/drain contact BCA.

The semiconductor device according to some embodiments of the present disclosure as fabricated by the above fabricating method may have the second insulating liner layer 152 disposed on a sidewall of at least a portion of the lower source/drain contact BCA. In addition, the first sacrificial pattern 141 and the first insulating liner layer 151 on the sidewall of the first sacrificial pattern 141 may be disposed under the first source/drain region SD1 to which the upper source/drain contact UCA is connected. Thus, the semiconductor device according to some embodiments of the present disclosure may improve the reliability of the electrical connection of the lower source/drain contact BCA.

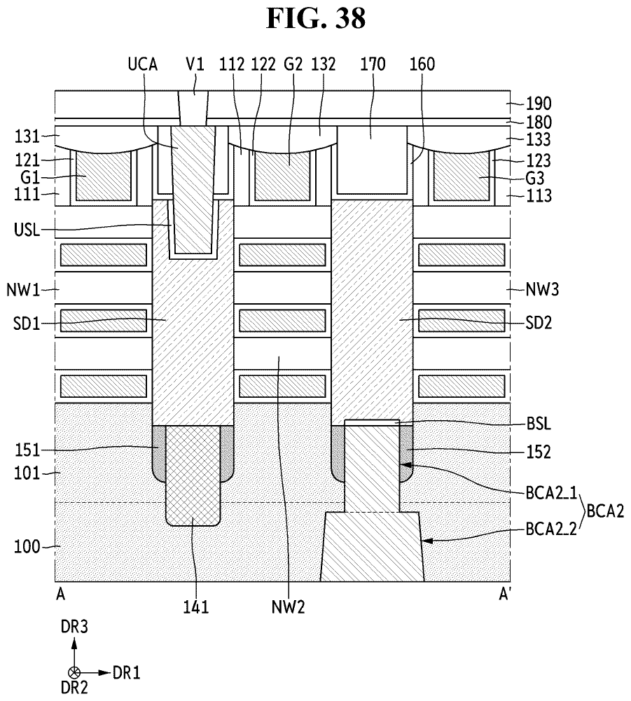

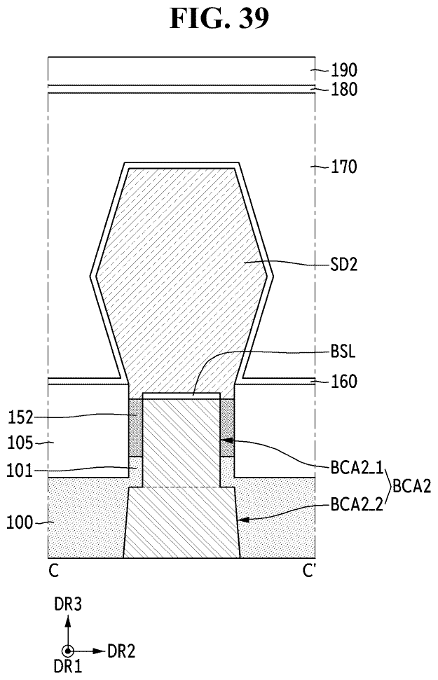

Hereinafter, a semiconductor device according to other embodiments of the present disclosure is described with referring to FIG. 38 and FIG. 39. Following description focuses on differences thereof from the semiconductor device as shown in FIG. 1 to FIG. 4.

FIG. 38 and FIG. 39 are cross-sectional views for illustrating a semiconductor device according to other embodiments of the present disclosure.

Referring to FIG. 38 and FIG. 39, in the semiconductor device according to further embodiments of the present disclosure, a lower source/drain contact BCA2 does not contact the lower surface of the second insulating liner layer 152.

The lower source/drain contact BCA2 may include a first portion BCA2_1 disposed between the second insulating liner layers 152 and a second portion BCA2_2 disposed under the first portion BCA2_1. An upper surface of the second portion BCA2_2 of the lower source/drain contact BCA2 may be spaced apart from the upper surface of the second insulating liner layer 152 in the vertical direction DR3. That is, the upper surface of the second portion BCA2_2 of the lower source/drain contact BCA2 does not contact the upper surface of the second insulating liner layer 152. For example, each of both opposing sidewalls in the second horizontal direction DR2 of the first portion BCA2_1 of the lower source/drain contact BCA2 may contact the insulating pattern 101.

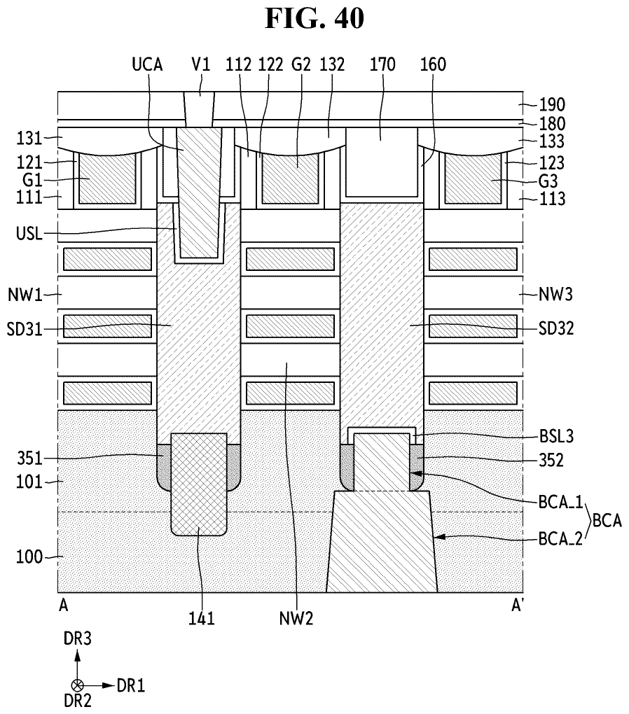

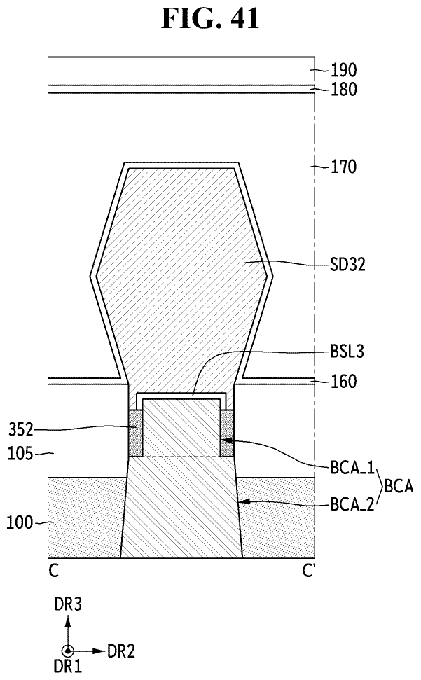

Hereinafter, with reference to FIG. 40 and FIG. 41, a semiconductor device according to still other embodiments of the present disclosure is described. Following description focuses on differences thereof from the semiconductor device as shown in FIG. 1 to FIG. 4.

FIG. 40 and FIG. 41 are cross-sectional views illustrating a semiconductor device according to other embodiments of the present disclosure.

Referring to FIG. 40 and FIG. 41, in the semiconductor device according to other embodiments of the present disclosure, a vertical level of the upper surface of the second insulating liner layer 352 may be lower than that of the upper surface of the lower source/drain contact BCA.

The upper surface of the first insulating liner layer 351 may be positioned at a lower vertical level than that of the upper surface of the first sacrificial pattern 141. Additionally, the upper surface of the second insulating liner layer 352 may be positioned at a lower vertical level than that of the upper surface of the first portion BCA_1 of the lower source/drain contact BCA. The first source/drain region SD31 may contact a portion of a sidewall facing in the first horizontal direction DR1 of the first sacrificial pattern 141. At least a portion of the second source/drain region SD32 may overlap with the first portion BCA_1 of the lower source/drain contact BCA in the first horizontal direction DR1. Additionally, at least a portion of the second source/drain region SD32 may overlap the first portion BCA_1 of the lower source/drain contact BCA in the second horizontal direction DR2. The lower silicide layer BSL3 may contact the upper surface of the second insulating liner layer 352.

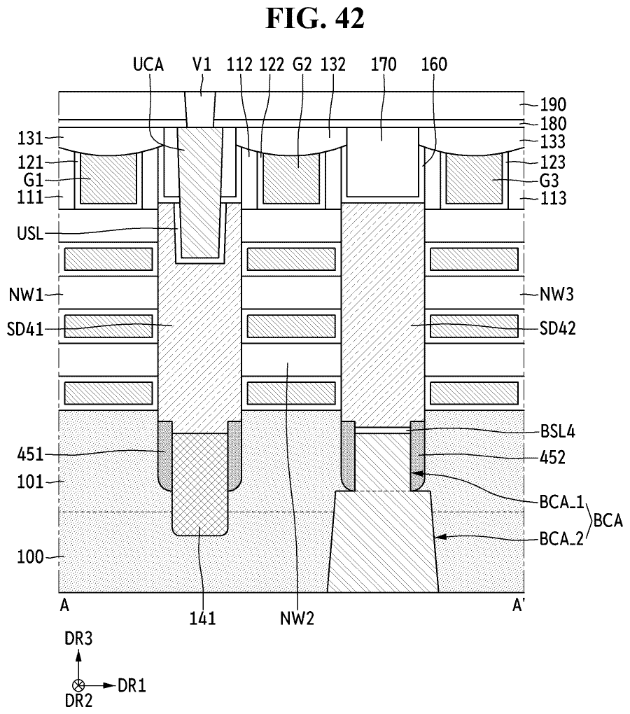

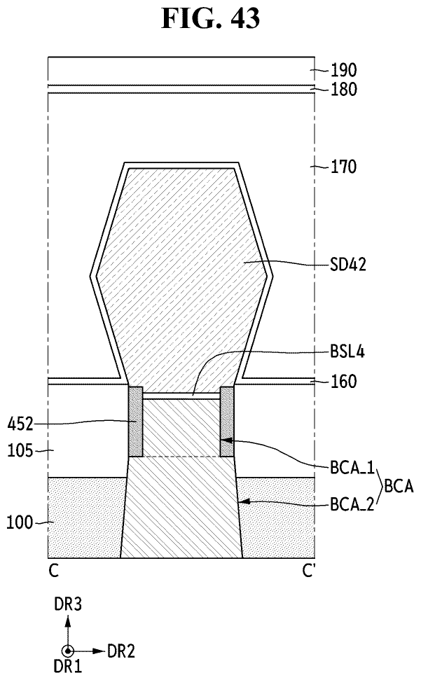

Hereinafter, with reference to FIG. 42 and FIG. 43, a semiconductor device according to yet other embodiments of the present disclosure is described. Following description focuses on differences thereof from the semiconductor device as shown in FIG. 1 to FIG. 4.

FIG. 42 and FIG. 43 are cross-sectional views for illustrating a semiconductor device according to other embodiments of the present disclosure.

Referring to FIG. 42 and FIG. 43, in the semiconductor device according to other embodiments of the present disclosure, a vertical level of the upper surface of the second insulating liner layer 452 may be higher than that of the upper surface of the lower source/drain contact BCA.

The upper surface of the first insulating liner layer 451 may be positioned at a higher vertical level than that of the upper surface of the first sacrificial pattern 141. Additionally, the upper surface of the second insulating liner layer 452 may be positioned at a higher vertical level than that of the upper surface of the first portion BCA_1 of the lower source/drain contact BCA. At least a portion of the first source/drain region SD41 may overlap the first insulating liner layer 451 in the first horizontal direction DR1. At least a portion of the first source/drain region SD41 may contact a portion of the sidewall facing in the first horizontal direction DR1 of the first insulating liner layer 451.

At least a portion of the second source/drain region SD42 may overlap the second insulating liner layer 452 in the first horizontal direction DR1. Additionally, at least a portion of the second source/drain region SD42 may overlap the second insulating liner layer 452 in the second horizontal direction DR2. At least a portion of the second source/drain region SD42 may contact a portion of the inner sidewall of the second insulating liner layer 452 in the first horizontal direction DR1. Additionally, at least a portion of the second source/drain region SD42 may contact a portion of an inner sidewall facing in the second horizontal direction DR2 of the second insulating liner layer 452.

A lower silicide layer BSL4 may contact the upper surface of the second insulating liner layer 452. For example, a sidewall facing in the first horizontal direction DR1 of the lower silicide layer BSL4 may contact the inner sidewall of the second insulating liner layer 452. Additionally, a sidewall facing in the second horizontal direction DR2 of the lower silicide layer BSL4 may contact the inner sidewall of the second insulating liner layer 452.

Although embodiments of the present disclosure have been described with reference to the accompanying drawings, the present disclosure is not limited to the above embodiments, but may be implemented in various different forms. A person skilled in the art may appreciate that the present disclosure may be practiced in other concrete forms without changing the technical spirit or essential characteristics of the present disclosure. Therefore, it should be appreciated that the embodiments as described above is not restrictive but illustrative in all respects.

What is claimed is:

1. A semiconductor device comprising:
a lower interlayer insulating layer;
an insulating pattern disposed on an upper surface of the lower interlayer insulating layer, the insulating pattern extending in a first horizontal direction;
a plurality of semiconductor nanosheets stacked on an upper surface of the insulating pattern with each semiconductor nanosheet being spaced apart from each other in a vertical direction;
a gate electrode that extends in a second horizontal direction different from the first horizontal direction on the insulating pattern, the gate electrode surrounding the plurality of semiconductor nanosheets with respect to a vertical cross sectional view;
a first source/drain region disposed on the insulating pattern at a first side of the gate electrode;
a second source/drain region disposed on the insulating pattern at a second side of the gate electrode opposite to the first side of the gate electrode in the first horizontal direction;
a lower source/drain contact that penetrates through the lower interlayer insulating layer and the insulating pattern in the vertical direction, the lower source/drain contact electrically connected to the second source/drain region, the lower source/drain contact including a first portion disposed under the second source/drain region, and a second portion disposed under the first portion; and
a first insulating liner layer in contact with a first sidewall and a second sidewall opposite the first sidewall in the first horizontal direction of the first portion of the lower source/drain contact, an upper surface of the first insulating liner layer in contact with the second source/drain region.

2. The semiconductor device of claim 1, wherein the first insulating liner layer is in contact with a first sidewall of the first portion of the lower source/drain contact and a second sidewall of the first portion of the lower source/drain contact, wherein the first sidewall of the first portion the lower source/drain contact is opposite the second sidewall of the first portion of the lower source/drain contact in the second horizontal direction.

3. The semiconductor device of claim 1, wherein a portion of a sidewall of the second source/drain region in the first horizontal direction continuously contacts a portion an outer sidewall of the first insulating liner layer in the first horizontal direction.

4. The semiconductor device of claim 1, wherein the first insulating liner layer does not overlap with the plurality of semiconductor nanosheets in the vertical direction and does not overlap with the gate electrode in the vertical direction.

5. The semiconductor device of claim 1, further comprising:
an upper interlayer insulating layer that covers the first and second source/drain regions; and
an upper source/drain contact that penetrates through the upper interlayer insulating layer in the vertical direction, the upper source/drain contact electrically connected to the first source/drain region.

6. The semiconductor device of claim 1, further comprising a field insulating layer on the upper surface of the lower interlayer insulating layer, the field insulating layer surrounding a sidewall of the insulating pattern,
wherein a vertical level of the upper surface of the first insulating liner layer is lower than a vertical level of an upper surface of the field insulating layer.

7. The semiconductor device of claim 1, further comprising a sacrificial pattern in contact with a lower surface of the first source/drain region, the sacrificial pattern comprising silicon germanium (SiGe).

8. The semiconductor device of claim 7, further comprising a second insulating liner layer in contact with both sidewalls of the sacrificial pattern in the first horizontal direction, an upper surface of the second insulating liner layer being in contact with the first source/drain region.

9. The semiconductor device of claim 1, wherein a lower surface of the first insulating liner layer is in contact with an upper surface of the second portion of the lower source/drain contact.

10. The semiconductor device of claim 1, wherein a lower surface of the first insulating liner layer is spaced apart from an upper surface of the second portion of the lower source/drain contact in the vertical direction.

11. The semiconductor device of claim 1, further comprising a lower silicide layer disposed between the lower source/drain contact and the second source/drain region, the lower silicide layer in contact with the upper surface of the first insulating liner layer.

12. The semiconductor device of claim 1, further comprising a lower silicide layer disposed between the lower source/drain contact and the second source/drain region, the lower silicide layer is in contact with an inner sidewall of the first insulating liner layer in the first horizontal direction.

13. A semiconductor device comprising:
a lower interlayer insulating layer;
an insulating pattern disposed on an upper surface of the lower interlayer insulating layer, the insulating pattern extending in a first horizontal direction;
a field insulating layer disposed on the upper surface of the lower interlayer insulating layer, the field insulating layer covering a sidewall of the insulating pattern;
a gate electrode on the insulating pattern and the field insulating layer, the gate electrode extending in a second horizontal direction different from the first horizontal direction;
a first source/drain region disposed on the insulating pattern at a first side of the gate electrode;
a second source/drain region disposed on the insulating pattern at a second side of the gate electrode opposite to the first side of the gate electrode in the first horizontal direction on the insulating pattern;
a lower source/drain contact that penetrates through the lower interlayer insulating layer and the insulating pattern in a vertical direction, the lower source/drain contact electrically connected to the second source/drain region;
a sacrificial pattern in contact with a lower surface of the first source/drain region, the sacrificial pattern comprising silicon germanium (SiGe);
a first insulating liner layer in contact with a first sidewall and a second sidewall of the sacrificial pattern, wherein the first sidewall is opposite the first sidewall in the first horizontal direction, an upper surface of the first insulating liner layer in contact with the first source/drain region; and
a second insulating liner layer in contact with at least a portion of a third sidewall and a fourth sidewall of the lower source/drain contact, wherein the fourth sidewall is opposite the third sidewall in the first horizontal direction, an upper surface of the second insulating liner layer in contact with the second source/drain region, a vertical level of the upper surface of the second insulating liner layer is lower than a vertical level of an upper surface of the field insulating layer.

14. The semiconductor device of claim 13, wherein an outer sidewall of the second insulating liner layer in the first horizontal direction is in contact with the insulating pattern and an outer sidewall of the second insulating liner layer in the second horizontal direction is in contact with the field insulating layer.

15. The semiconductor device of claim 13, wherein a vertical level of a lower surface of the first insulating liner layer is higher than a vertical level of a lower surface of the sacrificial pattern.

16. The semiconductor device of claim 13, wherein each of the first and second insulating liner layers includes a material different from a material of each of the insulating pattern and the lower interlayer insulating layer.

17. The semiconductor device of claim 13, wherein the upper surface of the second insulating liner layer is coplanar with an upper surface of the lower source/drain contact.

18. The semiconductor device of claim 13, wherein the vertical level of the upper surface of the second insulating liner layer is lower than a vertical level of an upper surface of the lower source/drain contact.

19. The semiconductor device of claim 13, wherein the vertical level of the upper surface of the second insulating liner layer is higher than a vertical level of an upper surface of the lower source/drain contact.

20. A semiconductor device comprising:
a lower interlayer insulating layer;
an insulating pattern extending in a first horizontal direction on an upper surface of the lower interlayer insulating layer;
a plurality of semiconductor nanosheets stacked on an upper surface of the insulating pattern with each semiconductor nanosheet of the plurality spaced apart from each other in a vertical direction;
a field insulating layer disposed on the upper surface of the lower interlayer insulating layer, the field insulating layer covering a sidewall of the insulating pattern;
a gate electrode extending in a second horizontal direction different from the first horizontal direction on the insulating pattern, the gate electrode surrounding each semiconductor nanosheet of the plurality of semiconductor nanosheets with respect to a vertical cross sectional view;
a first source/drain region disposed on the insulating pattern at a first side of the gate electrode;
a second source/drain region disposed on the insulating pattern at a second side of the gate electrode opposite to the first side of the gate electrode in the first horizontal direction;
an upper interlayer insulating layer that covers the first and second source/drain regions on the field insulating layer;
an upper source/drain contact that penetrates through the upper interlayer insulating layer in the vertical direction, the upper source/drain contact electrically connected to the first source/drain region;
a lower source/drain contact that penetrates through the lower interlayer insulating layer and the insulating pattern in the vertical direction, the lower source/drain contact electrically connected to the second source/drain region, the lower source/drain contact including a first portion disposed under the second source/drain region, and a second portion disposed under the first portion;
a sacrificial pattern in contact with a lower surface of the first source/drain region, the sacrificial pattern comprising silicon germanium (SiGe);
a first insulating liner layer in contact with a first sidewall and a second sidewall of the sacrificial pattern, wherein the first sidewall of the sacrificial pattern is opposite the second sidewall of the sacrificial pattern in the first horizontal direction of the sacrificial pattern, an upper surface of the first insulating liner layer in contact with the first source/drain region, a vertical level of a lower surface of the first insulating liner layer being higher than a vertical level of a lower surface of the sacrificial pattern; and
a second insulating liner layer in contact with a first sidewall and a second sidewall of the lower source/drain contact, wherein the first sidewall of the lower source/drain contact is opposite the second sidewall of the lower source/drain contact in the first horizontal direction of the first portion of the lower source/drain contact, an upper surface of the second insulating liner layer in contact with the second source/drain region, a vertical level of the upper surface of the second insulating liner layer being lower than a vertical level of an upper surface of the field insulating layer, and a lower surface of the second insulating liner layer in contact with an upper surface of the second portion of the lower source/drain contact.
